(19) United States
(12) Patent Application Publication
(10) Pub. No.: US 2026/0066234 A1
(43) Pub. Date: Mar. 5, 2026

(54) PLASMA ENHANCED EPITAXIAL DEPOSITION CHAMBER

(71) Applicant: Applied Materials, Inc., Santa Clara, CA (US)

(72) Inventors: Justin GAU, Santa Clara, CA (US); Rahul KOZHIKKALKANDI, Santa Claru, CA (US); Adib KHAN, Santa Clara, CA (US); Dmitry LUBOMIRSKY, Cupertino, CA (US); Ellie Y. YIEH, San Jose, CA (US)

(21) Appl. No.: 19/318,186

(22) Filed: Sep. 3, 2025

Related U.S. Application Data
(60) Provisional application No. 63/690,781, filed on Sep. 4, 2024.

(51) Int. Cl. H01J 37/32; C23C 16/455; C23C 16/458; C23C 16/507; C30B 25/10; C30B 25/12; C30B 25/14

(52) U.S. Cl. CPC H01J 37/3244; C23C 16/45508; C23C 16/4557; C23C 16/4586; C23C 16/507; C30B 25/105; C30B 25/12; C30B 25/14; H01J 37/3211; H01J 37/32183; H01J 37/32357; H01J 37/32522; H01J 2237/332

(57) ABSTRACT

Embodiments of the disclosure include a plasma processing chamber for forming an epitaxial layer. The plasma processing chamber will include a substrate support, a chamber lid positioned over the substrate support, a first inductively coupled plasma source positioned over the chamber lid, a substrate bias source, a gas ring disposed under the chamber lid, and a lower portion of the plasma processing chamber comprising an enclosure having an axis of symmetry. The substrate support comprising an electrode disposed within a body of the substrate support, and a substrate supporting surface disposed over the electrode and in a plasma processing region of the plasma processing chamber. The first inductively coupled plasma source comprises: a first coil positioned over the chamber lid, wherein the first coil comprises a first end and a second end, and the second end of the first coil is coupled to ground, and a first radio frequency (RF) power source, wherein an output node of the first RF power source is coupled to the first end of the first coil. The substrate bias source comprises a first power source that is coupled to the electrode of the substrate support. The gas ring comprises a plurality of nozzles that are configured to deliver a gas through an outlet of each of the nozzles to a portion of the plasma processing region disposed over the substrate supporting surface. A pumping port formed in the enclosure and the substrate support are concentrically aligned about the axis of symmetry of the enclosure.

### CROSS-REFERENCE TO RELATED APPLICATIONS

This application claims the benefit of United States Provisional Patent Application Ser. No. 63/690,781, filed Sep. 4, 2024, which is herein incorporated by reference.

### BACKGROUND

### Field

The present disclosure relates to an epitaxy growth system operable to deposit a high-quality epitaxial layer at a low processing temperature.

### Description of the Related Art

An integrated circuit is typically formed on a substrate by sequentially depositing conductive, semiconductive, or insulative layers on a semiconductor wafer. One fabrication step involves epitaxial deposition, i.e., depositing a crystalline film with a well defined orientation, e.g., single crystal silicon.

In traditional thermal epitaxial deposition processes, an epitaxial layer is formed on the surface of a substrate by heating the substrate to high temperature, such as between 1100° C. and 1200° C., in a processing chamber containing a hydrogen carrier gas mixed with one or more reactive gases, such as a silicon source gas or a dopant source gas. This results in a vapor deposition process can form the epitaxial layer. For example, silicon can be deposited using silicon tetrachloride (or germanium tetrachloride) and hydrogen as the component gases at approximately 1200-1250° C.

The growth of epitaxial films at low substrate temperature and pressure has been of increasing interest. However, at low substrate temperatures (≤500°C.), the epitaxy growth rate becomes extremely small (≤10 A/min), even using a high order silane such as trisilane or tetrasilane as the reactive gas. Moreover, at low pressure (≤100 mT) the dopant concentration drops.

Conventional systems generally operate at high temperatures, such as above 800° C. This operating temperature is relatively high, which not only needs a high thermal budget but also limits the application of the EPI process to those materials that can survive a high processing temperature.

Thus, a need exists for an improved epitaxy system, processing chamber, and epitaxial deposition processing method.

### SUMMARY

In one aspect of the disclosure, a plasma epitaxial chamber which utilizes plasma species to increase epitaxial growth rate and/or enable in-situ etch is provided.

Embodiments of the disclosure include a plasma processing chamber that comprises a substrate support, a chamber lid, an inductively coupled plasma source, a substrate bias source, a gas ring, and a lower portion of the plasma processing chamber comprising an enclosure. The substrate support comprising an electrode disposed within a body of the substrate support, and a substrate supporting surface disposed over the electrode and in a plasma processing region of the plasma processing chamber. The chamber lid is positioned over the substrate supporting surface and the plasma processing region. The inductively coupled plasma source is positioned over the chamber lid and operable to energize a process gas disposed within the plasma processing region. The inductively coupled plasma source comprises a first coil positioned over the chamber lid, wherein the first coil comprises a first end and a second end, a radio frequency (RF) power source, wherein an output node of the RF power source is coupled to the first end of the first coil, and a second coil, wherein the second coil comprises a first end and a second end, the first end of the second coil is coupled to the second end of the first coil, and the second end of the second coil is coupled to ground. The substrate bias source comprises a first power source that is coupled to the electrode of the substrate support. The gas ring is disposed under the chamber lid. The gas ring comprises a plurality of nozzles that are configured to deliver a gas through an outlet of each of the nozzles to a portion of the plasma processing region disposed over the substrate supporting surface. The lower portion of the plasma processing chamber comprising an enclosure having an axis of symmetry, wherein a pumping port formed in the enclosure and the substrate support are concentrically aligned about the axis of symmetry of the enclosure.

Embodiments of the disclosure may further include a plasma processing chamber that comprises a substrate support, a chamber lid, a first inductively coupled plasma source, a second inductively coupled plasma source, a substrate bias source, a gas ring, and a lower portion of the plasma processing chamber comprising an enclosure. The substrate support comprises an electrode disposed within a body of the substrate support, and a substrate supporting surface disposed over the electrode and in a plasma processing region of the plasma processing chamber. The chamber lid is positioned over the substrate supporting surface and the plasma processing region. The first inductively coupled plasma source is positioned over the chamber lid and operable to energize a process gas disposed within the plasma processing region. The first inductively coupled plasma source comprises a first coil positioned over the chamber lid, wherein the first coil comprises a first end and a second end, and the second end of the first coil is coupled to ground, and a first radio frequency (RF) power source, wherein an output node of the first RF power source is coupled to the first end of the first coil. The second inductively coupled plasma source that is operable to energize the process gas disposed within the plasma processing region. The second inductively coupled plasma source comprises a second coil positioned over the chamber lid, wherein the second coil comprises a first end and a second end, and the second end of the second coil is coupled to ground, and a second radio frequency (RF) power source, wherein an output node of the second RF power source is coupled to the first end of the second coil. The substrate bias source comprises a first power source that is coupled to the electrode of the substrate support. The gas ring is disposed under the chamber lid, wherein the gas ring comprises a plurality of nozzles that are configured to deliver a gas through an outlet of each of the nozzles to a portion of the plasma processing region disposed over the substrate supporting surface. The lower portion of the plasma processing chamber comprises an enclosure having an axis of symmetry, wherein a pumping port formed in the enclosure and the substrate support are concentrically aligned about the axis of symmetry of the enclosure.

Embodiments of the disclosure may further include a plasma processing chamber that comprises a substrate support, a chamber lid, a first inductively coupled plasma source, a substrate bias source, a gas ring, a heating element coupled to a body portion of the gas ring, and a lower portion of the plasma processing chamber comprising an enclosure. The substrate support comprises: an electrode disposed within a body of the substrate support, and a substrate supporting surface disposed over the electrode and in a plasma processing region of the plasma processing chamber. The chamber lid is positioned over the substrate supporting surface and the plasma processing region. The first inductively coupled plasma source is positioned over the chamber lid and operable to energize a process gas disposed within the plasma processing region, wherein the first inductively coupled plasma source comprises: a first coil positioned over the chamber lid, wherein the first coil comprises a first end and a second end, and the second end of the first coil is coupled to ground; and a first radio frequency (RF) power source, wherein an output node of the first RF power source is coupled to the first end of the first coil. The substrate bias source, wherein the substrate bias source comprises a first power source that is coupled to the electrode of the substrate support. The gas ring is disposed under the chamber lid, wherein the gas ring comprises a plurality of nozzles that are configured to deliver a gas through an outlet of each of the nozzles to a portion of the plasma processing region disposed over the substrate supporting surface. The heating element is configured to heat a gas flowing through a channel formed in the body portion of the gas ring, and the outlet of each of the nozzles is in fluid communication with the channel. The lower portion of the plasma processing chamber comprises an enclosure having an axis of symmetry, wherein a pumping port formed in the enclosure and the substrate support are concentrically aligned about the axis of symmetry of the enclosure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A illustrates a schematic top view of a processing system, according to an embodiment of the present application.

FIG. 1B illustrates a schematic top view of a processing system, according to an embodiment of the present application.

FIG. 2A illustrates a schematic cross-sectional view of a processing chamber, according to an embodiment of the present application.

FIG. 2B illustrates a schematic cross-sectional view of an alternate configuration of a processing chamber, according to an embodiment of the present application.

FIG. 2C is a cross-sectional view taken along lines 2c-2c of FIG. 2B, according to an embodiment of the present application.

FIG. 2D is a cross-sectional view taken along lines 2d-2d of FIG. 2B, according to an embodiment of the present application.

FIG. 2E schematically illustrates a radio frequency (RF) circuit configuration for generating a plasma in the processing chamber, according to an embodiment of the present application.

FIG. 3 illustrates a schematic cross-sectional view of a processing chamber, according to an embodiment of the present application.

FIG. 4A illustrates a schematic cross-sectional view of a dome lid structure, according to an embodiment of the present application.

FIG. 4B illustrates a schematic perspective view of a dome lid structure, according to an embodiment of the present application.

FIG. 4C illustrates a schematic cross-sectional view of an alternate configuration of the dome lid structure shown in FIG. 4A, according to an embodiment of the present application.

FIG. 5A illustrates a schematic cross-sectional view of a configuration of Callout 4-A in FIGS. 4A and 4C, according to an embodiment of the present application.

FIG. 5B illustrates a schematic perspective view of the top baffle 236 shown in FIG. 5A, according to an embodiment of the present application.

FIG. 5C illustrates a schematic cross-sectional view of the top baffle 236 shown in FIG. 5A, according to an embodiment of the present application.

FIG. 6 illustrates a schematic cross-sectional view of a configuration of Callout 4-B in FIG. 4A, according to an embodiment of the present application.

FIG. 7A illustrates a schematic perspective view of a gas ring liner, according to an embodiment of the present application.

FIG. 7B illustrates a schematic perspective view of the coupling configuration among the gas ring, the gas ring liner, and the side nozzles, according to an embodiment of the present application.

FIG. 7C illustrates a schematic cross-sectional view of the coupling configuration among the gas ring, the gas ring liner, and the side nozzles, according to an embodiment of the present application.

FIG. 7D illustrates a schematic cross-sectional view of a side nozzle 240, according to an embodiment of the present application.

FIG. 8 illustrates a schematic cross-sectional view of a processing chamber including the gas ring and the susceptor, according to an embodiment of the present application.

FIG. 9A illustrates a schematic top view of the showerhead, according to an embodiment of the present application.

FIG. 9B illustrates a schematic top view of the showerhead, according to an embodiment of the present application.

FIG. 10A illustrates a schematic cross-sectional view of the susceptor, according to an embodiment of the present application.

FIG. 10B illustrates a schematic top view of the heater body 1012 according to an embodiment.

FIG. 10C illustrates a schematic cross-sectional view of the heater body 1012.

FIG. 11 illustrates a schematic perspective view of the bottom liner, according to an embodiment of the present application.

FIG. 12 illustrates a schematic flow path of a purge gas according to an embodiment of the present application.

FIG. 13 illustrates operations of a cleaning method, according to an embodiment of the present application.

FIG. 14A illustrates a schematic cross-sectional view of a susceptor, according to an embodiment.

FIG. 14B illustrates a schematic cross-sectional view of a heater puck, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Embodiments of the disclosure provided herein include a plasma-enhanced epitaxial (PE-EPI) deposition chamber that is configured to form a low-defect-containing epitaxial film at a low process temperature. The EPI chamber includes a susceptor that conductively heats a substrate using a resistive heater. A radiative heat source may not be needed in the EPI chamber of the present application, essentially reducing the frequency to clean the dome of the EPI chamber. The substrate temperature during processing is controlled to be below 800° C., 600° C., 500° C., or even lower. The EPI growth rates at these low temperatures are compensated by increasing gas/plasma temperature and activating the surface (compensating lower surface temperature) of the substrate to increase mobility of adatoms landed on the substrate surface. Thus, one or more plasma sources are included in the EPI chamber for energizing the process gas. The plurality of plasma sources may be disposed around pipes of gas feeds, above and/or below the showerhead around the dome lid and/or side walls of the EPI chamber.

To further increase the growth rate at the low temperature, the kinetic energy of the incident ions/radicals may also be increased. The susceptor may be biased by an RF voltage to increase the kinetic energy of the adatoms independently from the rotational/vibrational modes.

To reduce energy loss to the environment and protect the other parts of the EPI chamber from erosion, the EPI chamber includes a plurality of internal liners that thermally isolate the dome and side walls of the EPI chamber from internal heat. As the liners are made of materials of low thermal conductance, such as quartz or coated base materials (e.g., metals or dielectrics), and are different from the dome and walls of the EPI chamber, the internal liners are separated from adjacent parts by separators to avoid thermal stress caused by mismatch of coefficient of thermal expansion (CTE). A process of purging process gases from the gaps between the internal liners and outside parts is implemented to prevent unnecessary deposition of materials or byproducts in those gaps and to prevent possible contamination during the processing of the next substrate.

To provide axisymmetric gas flow into the processing region, a gas feed with a plurality of feeding locations is included in the dome of the EPI chamber. In some embodiments, the gas feed structure includes a top flow baffle disposed at the center of the dome. The gas feed further includes a plurality of side nozzles disposed right above the showerhead around the side walls of the dome lid. A gas ring couples the plurality of the side nozzles and is protected by a gas ring liner. In some epitaxial deposition processes it is desirable to deliver the process gases to a gas plenum first and then flow through a showerhead into a processing region above a substrate disposed on the susceptor. However, in some other epitaxial deposition processes, it has been found that a showerhead that is positioned to separate portions of a processing region formed over the surface of a substrate can, in some configurations, undesirably decrease the time between chamber cleans and undesirably affect the properties of a plasma formed within a processing region during plasma-enhanced epitaxial deposition processes.

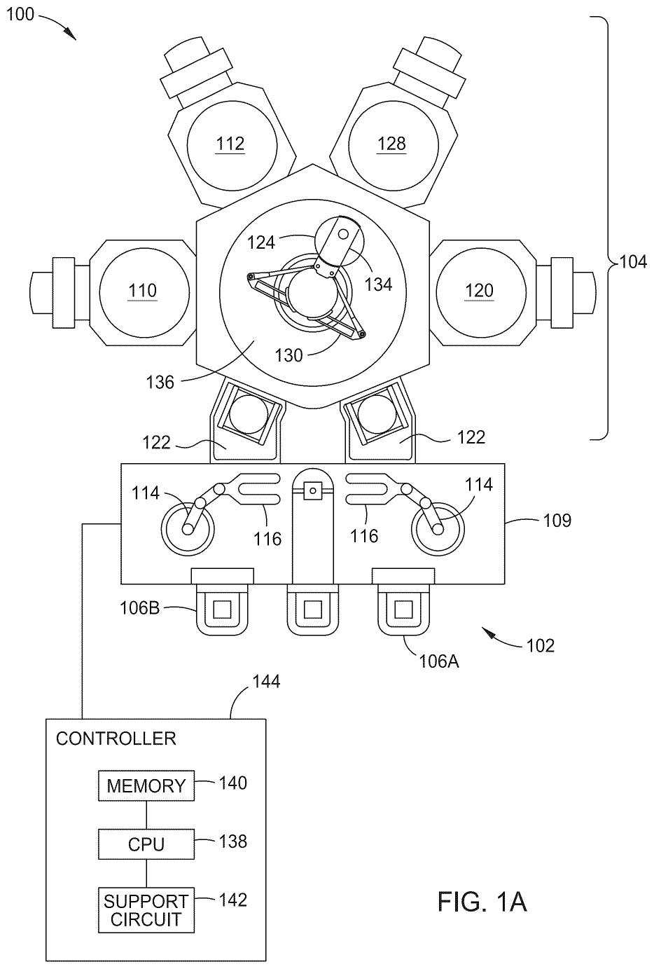

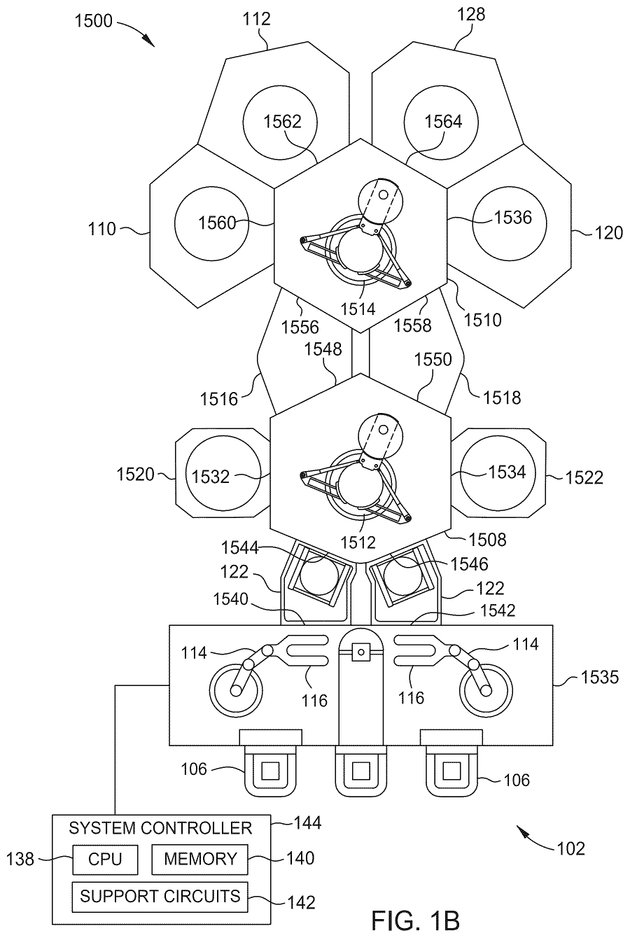

FIG. 1A illustrates a schematic top view of a processing system 100, according to one or more embodiments. The processing system 100 includes one or more load lock chambers 122 (two are shown in FIG. 1A), a processing platform 104, a factory interface 102, and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1A. The factory interface 102 is coupled to the transfer chamber 136 through the load lock chambers 122. According to an embodiment, each one of the plurality of processing chambers 110, 112, 120, and 128 may be a low temperature EPI chamber as set forth in the present application. According to an embodiment, one of the plurality of processing chambers 110, 112, 120, and 128 may be a preclean chamber configured to remove oxides from a substrate.

In one or more embodiments, the factory interface 102 includes at least one docking station 109 and at least one factory interface robot 114 to facilitate the transfer of substrates 124. The docking station 109 is configured to accept one or more front opening unified pods (FOUPs) 106. Two FOUPS 106A, 106B are shown in the implementation of FIG. 1A. The factory interface robot 114, having a blade 116 disposed on one end of the robot 114, is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1A) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present application). The controller 144 includes a central processing unit (CPU) 138, a memory 140 containing instructions, and support circuits 142 for the CPU. The controller 144 controls various items directly, or via other computers and/or controllers.

FIG. 1B is a schematic top view of a multi-chamber processing system 1500, according to one or more implementations of the present disclosure. The processing system 1500 includes a plasma-enhanced epitaxial chamber, such as processing chamber 200, described in greater detail below. The processing system 1500 generally comprises a factory interface 102, load lock chambers 122, transfer chambers 1508, 1510 with respective transfer robots 1512, 1514, holding chambers 1516, 1518, and processing chambers 1520, 1522, 110, 112, 120, 128. At least one of the processing chambers 1520, 1522, 110, 112, 120, 128 can be a plasma epitaxial chamber as described herein. As detailed herein, substrates in the processing system 1500 can be processed in and transferred between the various chambers without exposing the substrates to an ambient environment exterior to the processing system 1500 (e.g., an atmospheric ambient environment such as may be present in a fab). For example, the substrates can be processed in and transferred between the various chambers while being maintained at a low pressure (e.g., less than or equal to about 300 Torr) or vacuum environment without breaking the low pressure or vacuum environment among various processes performed on the substrates in the processing system 1500. Accordingly, the processing system 1500 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1B, the factory interface 102 includes a docking station 1535 and factory interface robots 114 to facilitate transfer of substrates. The docking station 1535 is adapted to accept one or more front opening unified pods (FOUPs) 106. In some examples, each factory interface robot 114 generally includes a blade 116 disposed on one end of the respective factory interface robot 114 adapted to transfer the substrates from the factory interface 102 to the load lock chambers 122.

The load lock chambers 122 have respective ports 1540, 1542 coupled to the factory interface 102 and respective ports 1544, 1546 coupled to the transfer chamber 1508. The transfer chamber 1508 further has respective ports 1548, 1550 coupled to the holding chambers 1516, 1518 and respective ports 1532, 1534 coupled to processing chambers 1520, 1522. Similarly, the transfer chamber 1510 has respective ports 1556, 1558 coupled to the holding chambers 1516, 1518 and respective ports 1560, 1562, 1564, 1536 coupled to processing chambers 110, 112, 120, 128. The ports 1532, 1534, 1536, 1540, 1542, 1544, 1546, 1548, 1550, 1556, 1558, 1560, 1562, 1564, can be, for example, slit valve openings with slit valves for passing substrates therethrough by the transfer robots 1512, 1514 and for providing a seal between respective chambers to prevent a gas from passing between the respective chambers. Generally, any port is open for transferring a substrate therethrough. Otherwise, the port can be closed.

The load lock chambers 122, transfer chambers 1508, 1510, holding chambers 1516, 1518, and processing chambers 1520, 1522, 110, 112, 120, 128 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 114 transfers a substrate from a FOUP 106 through a port 1540 or 1542 to a load lock chamber 122. The gas and pressure control system then pumps down the load lock chamber 122. The gas and pressure control system further maintains the transfer chambers 1508, 1510 and holding chambers 1516, 1518 with an interior low pressure or vacuum environment (which may include an inert gas). Hence, the pumping down of the load lock chamber 122 facilitates passing the substrate between, for example, the atmospheric environment of the factory interface 102 and the low pressure or vacuum environment of the transfer chamber 1508.

With the substrate in the load lock chamber 122 that has been pumped down, the transfer robot 1512 transfers the substrate from the load lock chamber 122 into the transfer chamber 1508 through the port 1544 or 1546. The robot 114 is then capable of transferring the substrate to and/or between any of the processing chambers 1520, 1522 through the respective ports 1532, 1534 for processing and the holding chambers 1516, 1518 through the respective ports 1548, 1550 for holding to await further transfer. Similarly, the transfer robot 1514 is capable of accessing the substrate in the holding chamber 1516 or 1518 through the ports 1548 or 1550 and is capable of transferring the substrate to and/or between any of the processing chambers 110, 112, 128, 120 through the respective ports 1560, 1562, 1564, 1536 for processing and the holding chambers 1516, 1518 through the respective ports 1556, 1558 for holding to await further transfer. The transfer and holding of the substrate within and among the various chambers can be in the low pressure or vacuum environment provided by the gas and pressure control system.

The processing chambers 1520, 1522, 110, 112, 120, 128 can be any appropriate chamber for processing a substrate. In one or more examples, the processing chamber 1520 can be capable of performing an etch process, the processing chamber 1522 can be capable of performing a cleaning process, the processing chamber 110 can be capable of performing a selective removal process, and the processing chambers 110, 112, 128, 120 can be capable of performing respective epitaxial growth processes. The processing chamber 1520 may be a Selectra™ Etch chamber available from Applied Materials of Santa Clara, Calif. The processing chamber 1522 may be a SiCoNi™ Pre-clean chamber available from Applied Materials of Santa Clara, Calif. The processing chamber 110, 112, 128, or 120 may be a Centura™ EPI chamber available from Applied Materials of Santa Clara, Calif. The present disclosure contemplates that the deposition operations and the etching operations described herein can be conducted in the same chamber (such as in the same deposition chamber) or can be conducted in multiple chambers.

A controller 144 is coupled to the processing system 1500 for controlling the processing system 1500 or components thereof. For example, the system controller 144 may control the operation of the processing system 1500 using a direct control of the chambers 122, 1508, 1510, 1516, 1518, 1520, 1522, 110, 112, 120, 128 of the processing system 1500 or by controlling controllers associated with the chambers 122, 1508, 1510, 1516, 1518, 1520, 1522, 110, 112, 120, 128. In operation, the system controller 144 enables data collection and feedback from the respective chambers to coordinate the performance of the processing system 1500.

The system controller 144 generally includes a central processing unit (CPU) 138, memory 140, and support circuits 142. The CPU 138 may be one of any form of a general purpose processor that can be used in an industrial setting. The memory 140, or non-transitory computer-readable medium, is accessible by the CPU 138 and may be one or more of memory such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote. The support circuits 142 are coupled to the CPU 138 and may comprise cache, clock circuits, input/output subsystems, power supplies, and the like. The various methods disclosed herein may generally be implemented under the control of the CPU 138 by the CPU 138 executing computer instruction code stored in the memory 140 (or in memory of a particular processing chamber) as, for example, a software routine. When the computer instruction code is executed by the CPU 138, the CPU 138 controls the chambers to perform processes in accordance with the various methods.

In one or more implementations, the processing system 1500 includes at least one of the following. The processing chamber 1520 can be a preclean chamber, for example, an Aktiv™ H2 Preclean chamber available from Applied Materials of Santa Clara, Calif. The processing chamber 1522 can be a preclean chamber, for example, an AJAX®, C preclean chamber available from Applied Materials of Santa Clara, Calif. The processing chambers 110, 112, 128, 120 can be a plasma enhanced epitaxial chamber, such as the processing chamber 200 described herein. In some embodiments, one or more of the processing chambers 110, 112, 120, 128 is a preclean chamber, for example, an AEF preclean chamber. In some embodiments, one or more of the processing chambers 110, 112, 120, 128 is an etch chamber, for example, a SYM3™ etch chamber available from Applied Materials, Inc. of Santa Clara, Calif. The processing system 1500 can be an integrated processing system that includes a plurality of processing chambers that will all work for pattern optimization.

The instructions stored in the memory 140 of the controller 144 can include one or more machine learning/artificial intelligence algorithms that can be executed in addition to the operations described herein. As an example, a machine learning/artificial intelligence algorithm executed by the controller 144 can generate, prioritize, accept, and/or reject signal profiles and/or data (such as metrology data and/or substrate map data) used in relation to the method. The machine learning/artificial intelligence algorithm can account for previous operational runs to monitor and update the signal profiles and/or data. The machine learning/artificial intelligence algorithm can optimize process parameter(s) of process recipes. The one or more machine learning/artificial intelligence algorithms can use, for example, a regression model (such as a linear regression model) or a clustering technique to estimate optimized parameters and/or optimized values for signal profiles and/or data. The algorithm(s) can be unsupervised or supervised. In one or more implementations, the controller 144 automatically conducts the operations described herein without the use of one or more machine learning/artificial intelligence algorithms. In one or more implementations, the controller 144 compares measurements to data in a look-up table and/or a library to optimize process parameters. The controller 144 can store measurements as data in the look-up table and/or the library.

Other processing systems can be in other configurations. For example, more or fewer processing chambers may be coupled to a transfer apparatus. In the illustrated example, the transfer apparatus includes the transfer chambers 1508, 1510 and the holding chambers 1516, 1518. In one or more examples, more or fewer transfer chambers (e.g., one transfer chamber) and/or more or fewer holding chambers (e.g., no holding chambers) may be implemented as a transfer apparatus in a processing system.

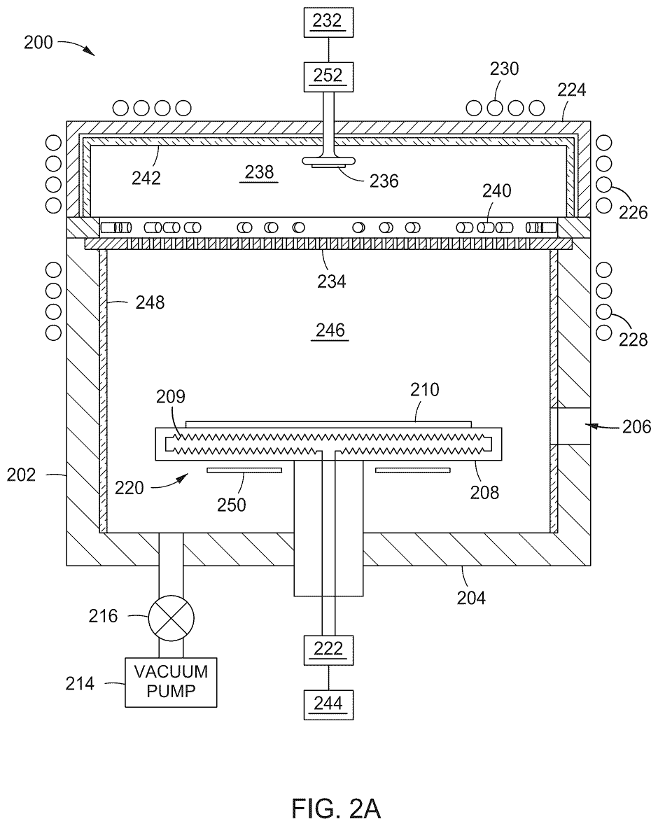

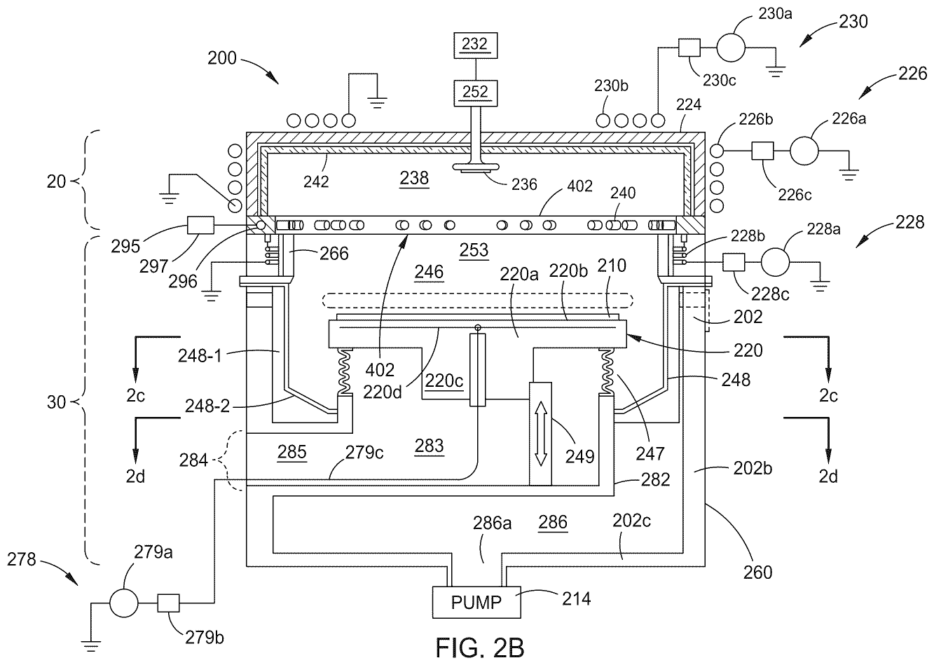

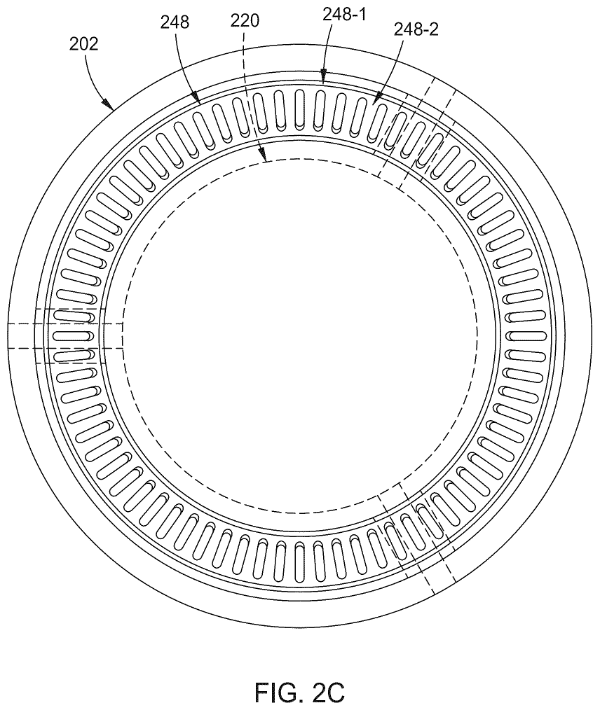

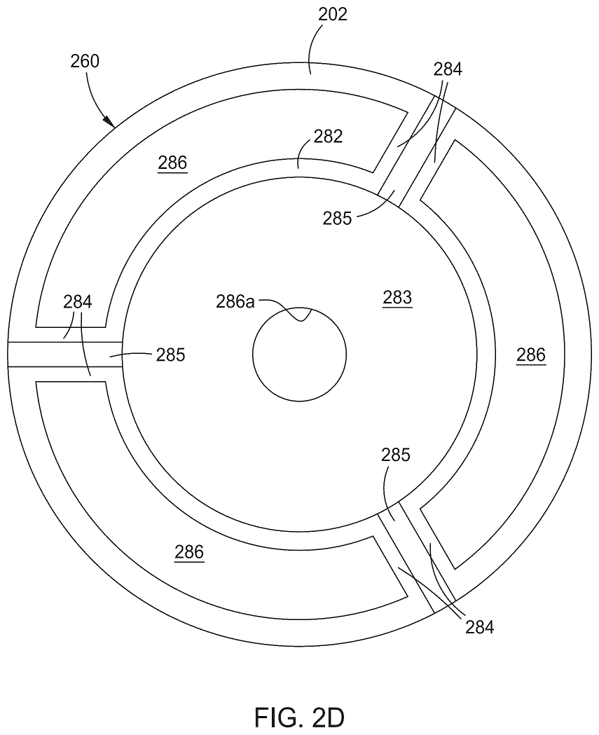

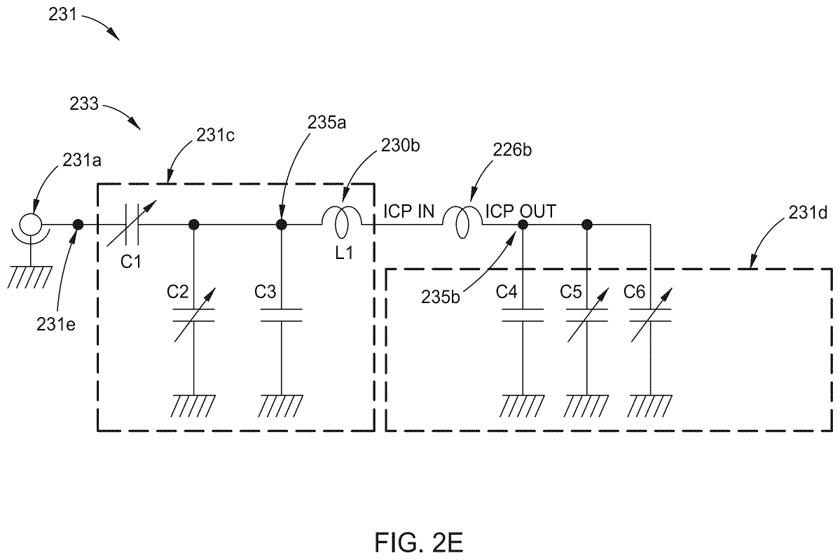

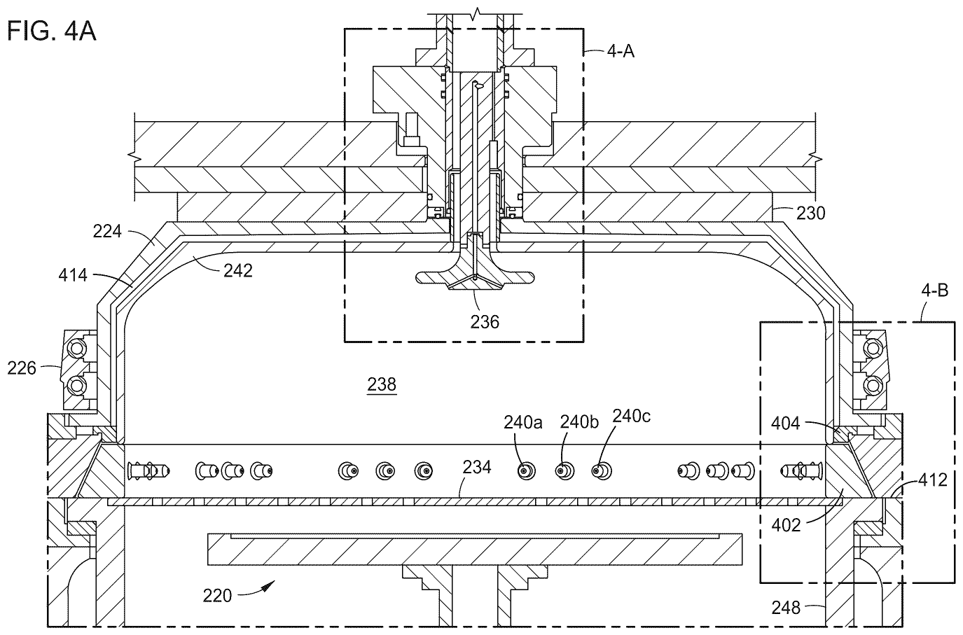

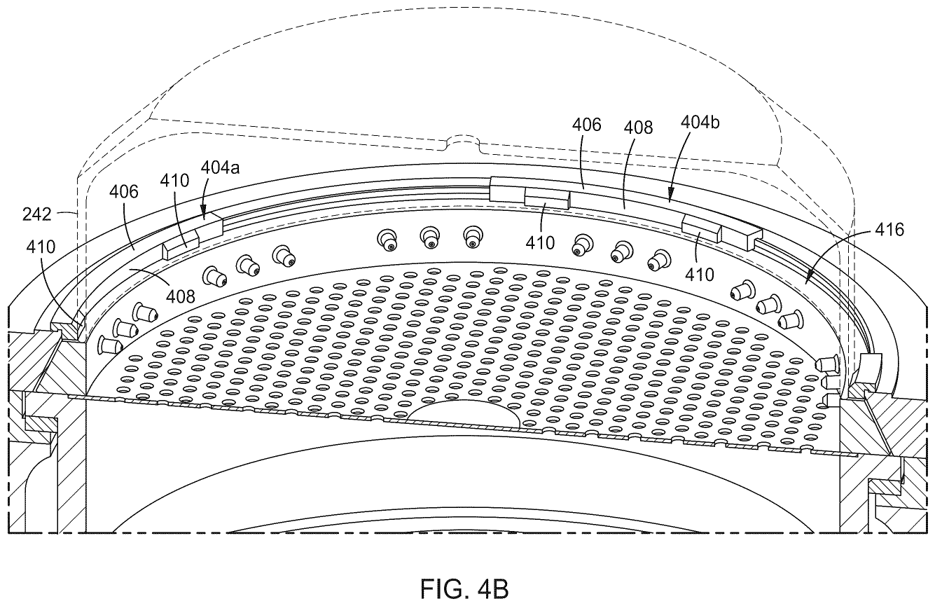

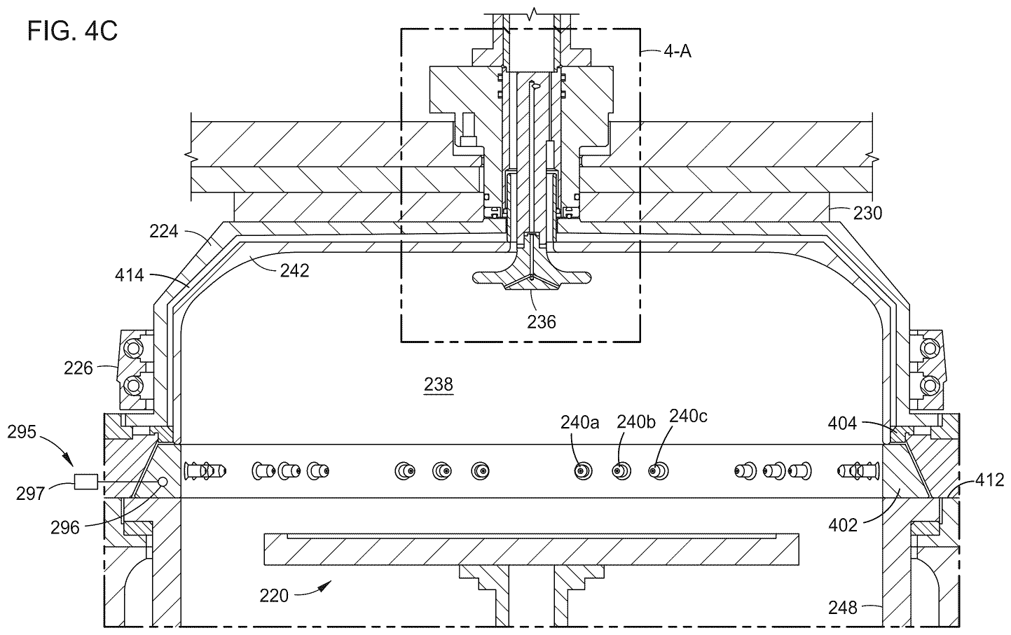

FIG. 2A illustrates a schematic cross-sectional view of a processing chamber 200 according to an embodiment. The processing chamber 200 may be any one of the processing chambers 110, 112, 128, and 120 as shown in FIGS. 1A-1B and operable to deposit an EPI layer at a low temperature. The processing chamber 200 in FIG. 2A includes side walls 202, a bottom 204, a chamber lid 224, and a plurality of internal liners, including an upper lid liner 242 and a lower wall liner 248. The chamber lid 224, the side walls 202, and the bottom 204 together enclose a processing region 246. A susceptor 220, which is also referred to herein as substrate support, is disposed in the processing region 246 and supports a substrate 210 thereon during processing. The side walls 202 include a plurality of ports 206 for transferring the substrate 210 in or out of the processing chamber 200. The upper lid liner 242 and the lower wall liner 248 are configured to insulate the lid 224 and the side walls 202, respectively, from the internal heat. According to an embodiment, the chamber lid 224 may be made of metal, such as aluminum or stainless steel, and the upper lid liner 242 and the lower wall liner 248 may be made of thermal insulators, such as ceramic or quartz. The liners are configured to conform to the shape of the lid 224 and the side walls 202. Other liners, such as a gas ring liner 402 in FIG. 4A, may also be utilized to protect other components of the processing chamber 200.

The processing chamber 200 further includes a vacuum pump 214 and a plurality of gas sources 232 containing a carrier gas, a deposition gas, a purge gas, and a cleaning gas. The gases may be provided into the processing chamber via a gas feed. The gas feed may include a top baffle 236 disposed at a central part of the lid 224 and a plurality of side nozzles 240 disposed along side walls of the lid 224. The remote plasma source 252 may be coupled with the gas feed of one or more of the gas sources 232 and configured to energize each process gas independently or energize a mixture of two or more of the process gases. The energized process gas is provided to the chamber 200 via the top baffle 236. The vacuum pump 214 is coupled to the processing chamber 200 and configured to adjust the vacuum level within the process region 246 via a valve 216. Vacuum pump 214 is also configured to evacuate spent gases from the processing chamber 200. According to an embodiment, the wall liners 248 includes an open lower end configured to allow process gases to flow through.

Optionally, the processing chamber 200 also includes a gas plenum region 238 that is bounded by a showerhead 234 and upper lid liner 242. The gas sources 232 provide process gases into the gas plenum region 238 first via the top baffle 236. The gas showerhead 234 includes a plurality of conduits that allow the process gases to flow therethrough. The gas plenum region 238 and the showerhead 234 are configured to improve an axisymmetric flow pattern of process gases into the process region 246.

The processing chamber 200 further includes a heating unit 222 coupled with the susceptor 220. The heating unit 222 includes heating elements 209 disposed in a body 208. According to an embodiment, the heating elements 209 are resistive heaters. In some embodiments, as illustrated in FIG. 2B, the susceptor 220 includes a pedestal 220a. For simplicity of illustration, the heating elements 209 have been removed from FIG. 2B to illustrate other features of the susceptor 220. However, the heating elements 209 can be disposed within the body portion 208 of the pedestal 220a of the susceptor 220. In some configurations, the body portion 208 of the pedestal 220a can include a metal and/or a dielectric material. The heating unit 222 may also include bias electrodes (e.g., electrode 220d (FIG. 2B)) configured to provide a bias voltage to the susceptor 220. When an RF bias or DC voltage bias is applied to one or more of the electrodes, the biased one or more electrodes can increase the kinetic energy of the ions formed in a plasma and add directionality. The bias electrodes are formed within a dielectric material containing portion of the body portion of the pedestal 220a. The dielectric material containing portion of the body of the susceptor 220 can include a material, such as boron nitride (BN), aluminum nitride (AlN), aluminum oxide (Al₂O₃), or other useful material.

The heating unit 222 and the susceptor 220 may be coupled with a lifter 244 configured to lift up and lower down the susceptor 220 and the heating unit 222. The heating unit 222 is configured to adjust the temperature of the substrate within a predetermined range, such as 100 to 800° C., 100 to 700° C., 100 to 600° C., 100 to 500° C., or 100 to 400° C., or other suitable temperature range.

As the substrate 210 has a low temperature during EPI growth, the processing chamber 200 includes a plurality of plasma sources 226, 228, 230 disposed at various locations of the processing chamber 200 to energize the process gases. As discussed further below, in some embodiments, the processing chamber 200 can include a substrate bias source 278 to bias the substrate and generate and/or sustain a plasma formed in the processing region 246. After energization, the reactants of the process gases, such as radicals and ions, have a high energy that can increase both growth rate and uniformity of deposited materials. As shown in FIG. 2A, a plasma source 230 may be disposed at a top surface of the lid 224, and/or another plasma source 226 is disposed at an outer edge or around the side walls of the lid 224. The plasma sources 230 and 226 are operable to energize the process gases above the showerhead 234, such as within the gas plenum region 238. Another plasma source 228 may disposed along side walls 202 and is operable to energize the process gases between the showerhead 234 and the susceptor 220. Furthermore, a remote plasma source 252 may be disposed outside the lid 224 and operable to energize the process gases prior to entering the plenum region 238. The plasma sources 252, 230, 226, and 228 can be controlled independently or collectively by the controller 144 depicted in FIGS. 1A-1B.

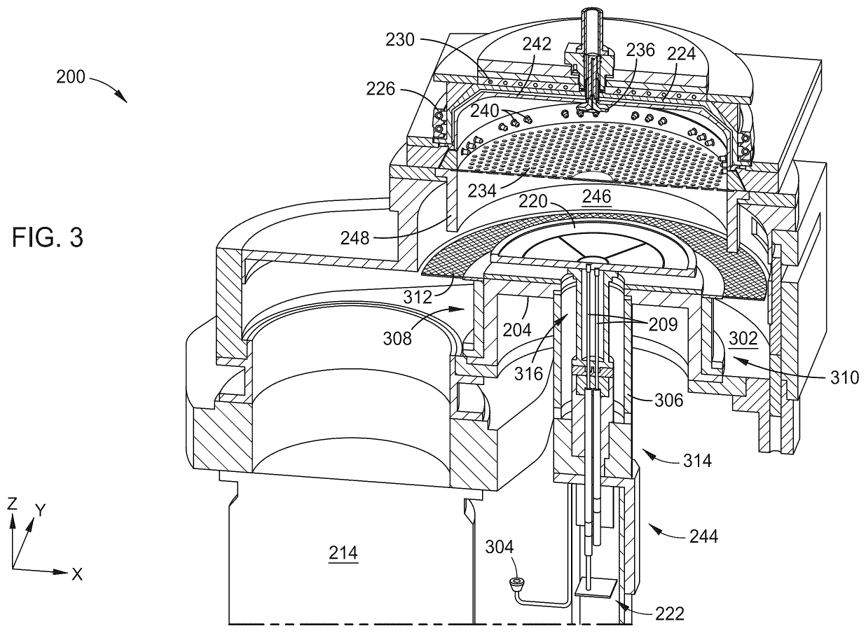

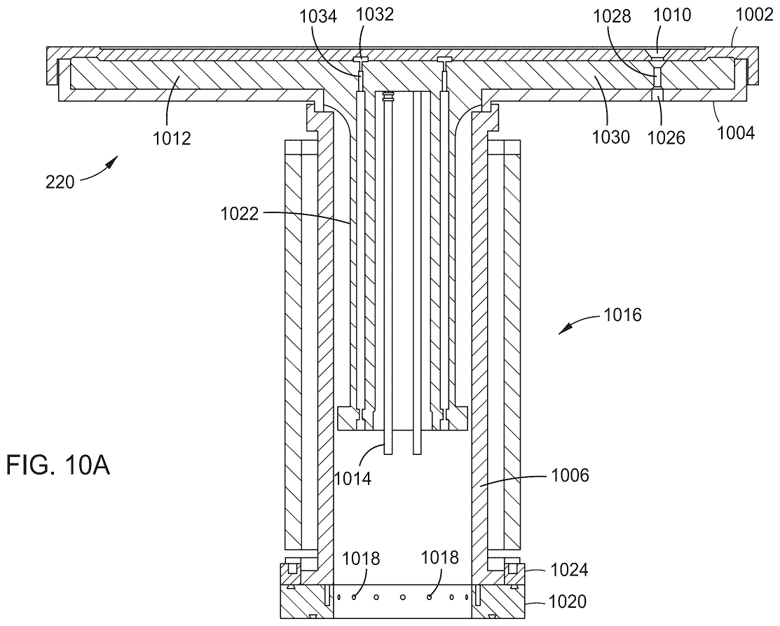

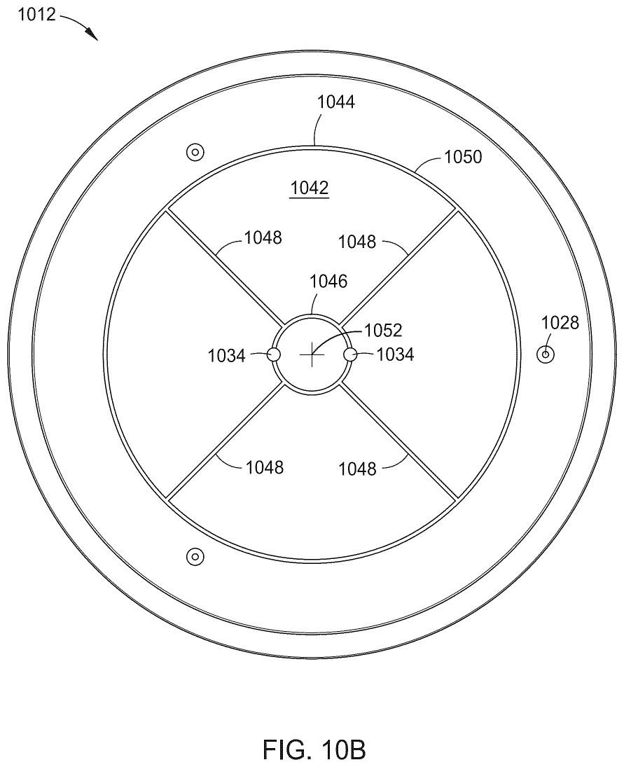

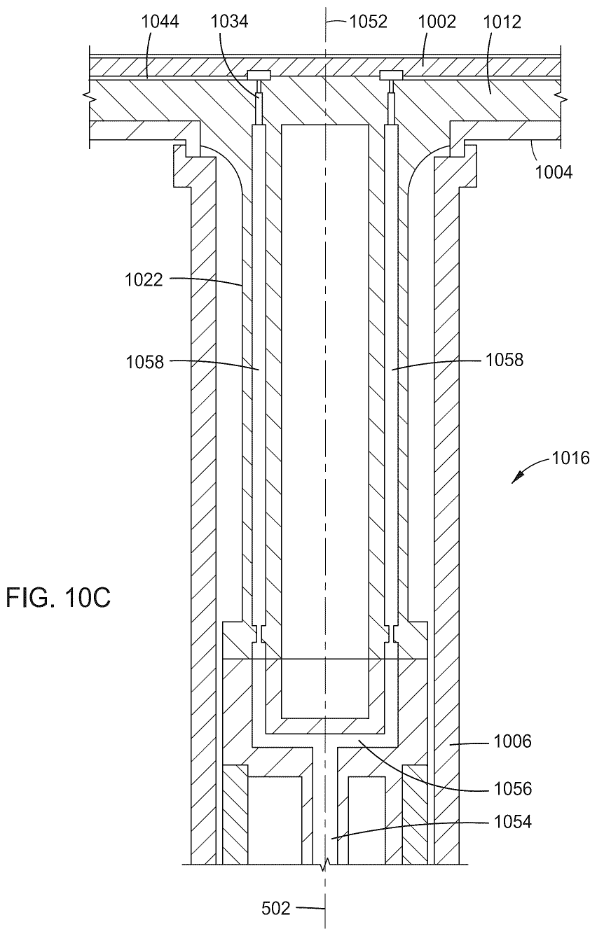

FIG. 3 illustrates a schematic cross-sectional view of a processing chamber 200 according to an embodiment. Similar components in FIGS. 2A and 3 are indicated with identical reference numerals. Comparing with FIG. 2A, the processing chamber 200 in FIG. 3 further includes a vacuum plenum 302, a protective sleeve 306 for the susceptor 220 (also shown as 1016 in FIG. 10), and a purge gas inlet 304. The vacuum plenum 302 couples the vacuum pump 214 with the processing region 246 via the bottom of the processing chamber 200. The vacuum plenum 302 is configured to even the vacuum level across the process region 246 such that process gases within the processing region 246 are evenly drawn across the substrate disposed on the susceptor 220. The vacuum plenum 302 couples with the vacuum pump 214 via a lower surface of the vacuum plenum 302 and couples with the process region 246 via an upper surface of the vacuum plenum 302. The vacuum pump 214 can be side-mounted or coaxially-mounted with regard to the processing region 246. According to an embodiment, the upper surface of the vacuum plenum 302 may be a charged screen 312 that is capable of attracting radicals in the plasma and preventing the same from entering the vacuum plenum 302 and subsequent processing lines. The charge screen 312 can also function as a pump liner configured to correct the skew of pressure caused by an offset pump. For example, a higher density of holes may be arranged at a distal end of the charge screen 312, which is far away from the vacuum pump 214, than at a proximal end of the charge screen 312, which is adjacent to the vacuum pump 214. In another example, holes at the distal end may have a larger diameter than holes at the proximal end.

FIG. 3 illustrates a side-mounted vacuum pump 214, where the vacuum plenum 302 extends from the vacuum pump 214 to surround a support column of the susceptor 220 along the bottom 204 of the processing chamber 200. The vacuum plenum 302 includes a proximate end 308 that is close to the vacuum pump 214 and a distal end 310 that is distant to the vacuum pump 214. The proximate end 308 is configured to have a larger dimension than the distal end 310 to facilitate an even drawing of the process gases from the processing region 246.

As the susceptor 220 may be lifted up by the lifter 244, the sleeve 306 is configured to provide a purged conduit 316 for the susceptor 220 to move up and down without leaking a substantial amount of process gases. A purge gas flows through the purged conduit 316 to prevent the deposition of materials below the susceptor 220. A detailed description of the sleeve 306 and the susceptor 220 will be provided later with regard to FIG. 10A. The purge gas inlet 304 is coupled with a purge gas source (not shown) and is configured to flow the purge gas into the conduit formed by the sleeve 306.

FIG. 2B illustrates a schematic cross-sectional view of an alternate embodiment of the processing chamber 200. FIG. 2C is a cross-sectional view taken along lines 2c-2c of FIG. 2B. FIG. 2D is a cross-sectional view taken along lines 2d-2d of FIG. 2B. As will be discussed further below, an alternate configuration of the processing chamber 200, as illustrated in FIG. 2B, doesn't include the showerhead 234 separating the processing region 246 and plenum region 238 of the processing chamber 200. Thus, a plasma processing region 253, which includes the processing region 246 and plenum region 238, is formed over a substrate 210. By use of the plasma sources 226, 228, and 230, a plasma is formed within the plasma processing region 253 during a plasma processing step performed within the processing chamber 200.

The processing chamber 200 depicted in FIG. 2B includes an upper portion 20 and a lower portion 30. As discussed above, the processing chamber 200 includes a side wall 202 and a lid 224. The side wall 202 has an axially symmetrical shape, such as a cylinder. The side wall 202 includes an axially symmetrical (e.g., cylindrical) dielectric side window 266 and a chamber liner 248, which may be formed of metal.

The susceptor 220 inside the processing chamber 200 includes the pedestal 220a having a workpiece support surface 220b facing the lid 224 for holding a substrate 210, and a post 220c supporting the pedestal 220a. A processing region 246 of the processing chamber 200 is confined by the lid 224, the pedestal 220a and the side wall 202. The pedestal 220a may include an internal electrode 220d that is embedded with the body portion of the pedestal 220a. As noted above, the body portion of the pedestal 220a can include a dielectric material, such as such as boron nitride (BN), aluminum nitride (AlN), aluminum oxide (Al₂O₃), or other useful material. Optionally, an electrostatic chucking (ESC) voltage and/or RF plasma bias power may be supplied to the internal electrode 220d via a cable 220e extending through the post 220c. The cable 279c may be coupled to an substrate bias source 278, which includes an RF impedance match network 279b and/or an RF power generator 279a. The substrate bias source 278 is configured to provide an RF bias to the electrode 220d. The cable 279c may be provided as a coaxial transmission line, which may be rigid (or flexible), or as a flexible coaxial cable.

The plasma sources 226, 228, 230 and substrate bias source 278 can provide a desired amount of RF power to the coils 226b, 228b, 230b, or electrode 220d through a matching circuit 226c, 228c, 230c, 279b by use of a respective RF power source 226a, 228a, 230a, or 278a. The RF power sources 226a, 228a, 230a, or 279a can provide an RF power, for example, that is less than about 1,000 W (but not limited to about 1,000 W) at a frequency of, for example, between about 100 kHz and 120 MHz, although other frequencies and powers may be provided as desired for particular applications. The RF power sources 226a, 228a, 230a, and 279a may be capable of producing either or both of continuous or pulsed power to their respective coil 226b, 228b, 230b, or electrode 220d. In some examples, the RF power sources 226a, 228a, 230a, and 279a may be capable of providing multiple frequencies that range between 400 kilohertz (kHz) and 60 megahertz (MHz). In one processing example, the RF power source 230a of the plasma source 230 is configured to provide an RF signal at a frequency between 500kHz and 2 MHz and RF power of between 1 W and 1000 W to the coil 230b, the RF power source 228a of the plasma source 228 is configured to provide an RF signal at a frequency between 2 MHz and 13.56 MHz and RF power of between 1 W and 1000 W to the coil 228b, the RF power source 226a of the plasma source 226 is configured to provide an RF signal at a frequency between 500 kHz and 2 MHz and RF power of between 1 W and 1000 W to the coil 226b, and the RF power source 279a of the substrate bias source 278 is configured to provide an RF signal at a frequency between 1 MHz and 60 MHz (e.g., 13.56 MHz) and RF power of between 1 W and 1000 W to the electrode 220d.

The chamber liner 248 is enclosed within a lower chamber body 260 that includes a cylindrical lower chamber body side wall 202b and a lower chamber body floor 202c. The lower chamber body 260 is also referred to herein as an enclosure that is configured to surround the structure and components that are positioned within the lower portion of the processing chamber 200. The lower chamber body side wall 202b and the lower chamber body floor 202c enclose an evacuation region 271. The chamber liner 248 includes an upper cylindrical section 248-1 and a lower annular grid 248-2 in the form of an inverted truncated cone. A vacuum pump 214 is disposed in a vacuum pump opening 286a (i.e., pumping port) in the floor 202c and is centered relative to the axis of symmetry of the side wall 202. In this configuration, the vacuum pump opening 286a (i.e., pumping port) formed in the floor 202c and the susceptor 220 are concentrically aligned about the axis of symmetry of the side wall 202. A containment wall 282 is coaxial with the susceptor 220 and a flexible bellows 247 extending between the pedestal 220a and the containment wall 282 enclose the susceptor 220 in an internal central space 283. The central space 283 is isolated from the volume evacuated by the vacuum pump 214, including the evacuation region 286 and the processing region 246.

Referring to FIGS. 2B, 2C and 2D, there are three hollow radial struts 284 defining radial access passages 285 spaced at 120 degree intervals extending through the chamber body side wall 202b and providing access to the central space 283. Three axial exhaust passages (i.e., evacuation regions 286 (FIGS. 2A and 2D)) are defined between the three radial struts 284. Different utilities may be provided through different ones of the radial access passages 285, including the RF power cable 132 connected to the electrode 220d, heater voltage supply lines connected to heater elements in the susceptor 220, an electrostatic chucking voltage supply line connected to the electrode 220d, coolant supply lines and helium supply lines for backside helium gas channels in the workpiece support surface 220b, for example.

A workpiece support lift actuator 249 is fixed with respect to the chamber body and moves the susceptor 220 axially. The workpiece support lift actuator 249 may be used to vary the distance between the substrate 210 and the lid 224. Varying this distance varies the plasma distribution across the surface of the substrate 210. Movement of the lift actuator may be used to improve uniformity of distribution of ions and/or radicals (e.g., PE-EPI process) across the surface of the substrate 210. The lift actuator 249 may be controlled by the user through the controller 144, for example.

The axially centered exhaust assembly, including the vacuum pump opening 286a and the formed axial exhaust passages, avoids asymmetries or skew in the gas flow and plasma distribution across the surface of the substrate 210 during processing. The annular grid 248-2, which may be grounded, masks the plasma processing region 253 from the discontinuities in the lower chamber body 260 and evacuation region 286, and the effects of the radial struts 284. The combination of the axially centered exhaust assembly (e.g., pump 214) with the symmetrical distribution of RF current flow below the susceptor 220 minimize any asymmetric plasma skew commonly seen in non-symmetric chamber designs and thus enhance processes uniformity in the plasma processing region 253.

FIG. 2E schematically illustrates a radio frequency (RF) circuit 233 for generating an inductively coupled plasma (ICP) in the processing chamber 200 by use of an inductively coupled plasma source 231 and coils 226b and 230b, according to an embodiment of the present application. The configuration illustrated in FIG. 2E can be used to simplify the processing chamber's RF power delivery configuration illustrated in FIG. 2B by removing the need for one of the plasma sources 226 or 230. In one embodiment, the inductively coupled plasma source 231 is configured to provide an RF signal at an RF power level to the series-connected coils 226b and 230b, which are positioned within the upper portion 20 of the processing chamber 200. The plasma generator 231a of the inductively coupled plasma source 231 is configured to deliver the RF signal to an output node 231e of the plasma generator 231a that is coupled to the series-connected coils 226b and 230b through a first matching circuit 231c and then from the series-connected coils 226b and 230b, and through a second matching circuit 231d. The first matching circuit 231c includes a series-connected variable capacitor C1, a first shunt capacitor C2, and a second shunt capacitor C3 that are coupled to an input node 235a of the coil 230b. The input of the series-connected variable capacitor C1 is coupled to an output node of the plasma generator 231a. The first shunt capacitor C2 can include a variable capacitor that can be varied in combination with the series-connected variable capacitor C1 to maximize power transfer from the plasma generator 231a to a load (e.g., coils 226b and 230b (e.g., inductive load)) and minimize reflected power. The second matching circuit 231d includes a plurality of parallel-connected capacitors, such as a fourth capacitor C4, a fifth capacitor C5, and a sixth capacitor C6 that are each coupled at one end to an output node 235b of the coil 226b and to a ground reference on the opposing end. In one embodiment, the fifth capacitor C5 and a sixth capacitor C6 of the second matching circuit 231d are variable capacitors that can be varied to adjust the voltage formed across the coils 226b and 230b, when the RF signal is applied from the plasma generator 231a, to adjust the capacitive coupling to a plasma formed in the processing region 246 and/or plenum region 238. In one example, the capacitance values for the fixed and variable capacitors can be within a range between 800-8000 picofarads (pF). In configurations similar to the configuration shown in FIG. 2B, which doesn't include the showerhead 234 separating the processing region 246 and plenum region 238, the control of the circuit elements in the first matching circuit 231c and the second matching circuit 231d, by use of commands from the controller 144, can significantly improve the control of the plasma density, plasma ion energy, and plasma uniformity, and thus improve one or more aspects of an epitaxial layer deposition process. One skilled in the art will appreciate that excessive bombardment of the growing epitaxial layer with energetic plasma-generated ions can undesirably alter the crystalline structure of the growing epitaxial layer and thus create defects in the formed epitaxial layer. Therefore, there is a need to adjust, tune, and control the plasma properties during plasma processing by controlling the RF signals (e.g., amplitude, phase, etc.) provided to the coils 236b, 228b, 230b, and electrode 220d during plasma processing. RF plasma generator 231a can provide an RF power, for example, that is less than about 1,000 W (but not limited to about 1,000 W) of radio frequency (RF) energy at one or more frequencies of, for example, in a range between 500 kHz and 60 MHz, such as between 1 and 2 MHz, although other frequencies and powers may be provided as desired for particular applications.

In some embodiments, the plasma source 228 and the inductively coupled plasma source 231 are used in combination during processing to control the plasma density, plasma uniformity, ion energy, and other plasma processing parameters to improve an EPI deposition process performed on a substrate 210. In this case, the components within the plasma source 228 are configured to control various aspects of the plasma, such as the shape of the plasma, the lateral or azimuthal plasma distribution, and/or plasma properties (e.g., ion energy, plasma density, etc.) in the processing region 246 of the plasma processing region 253 of the processing chamber 200.

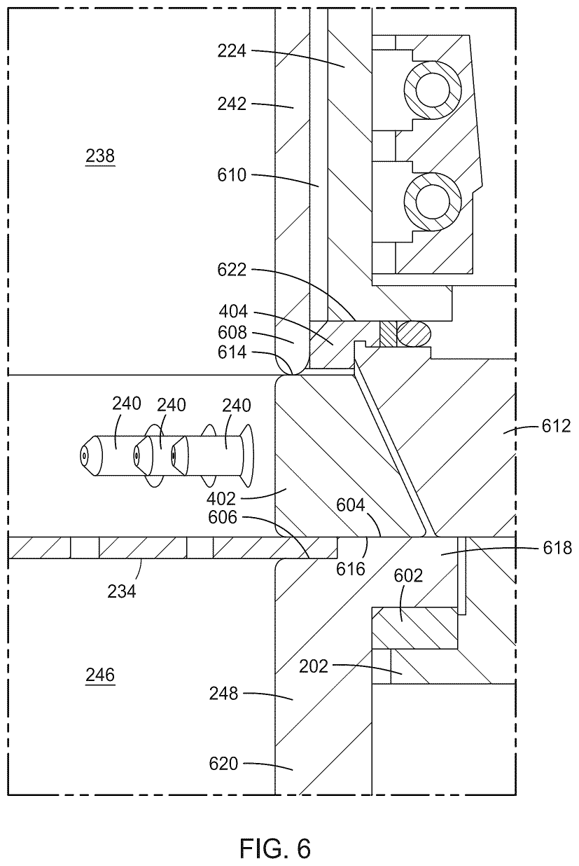

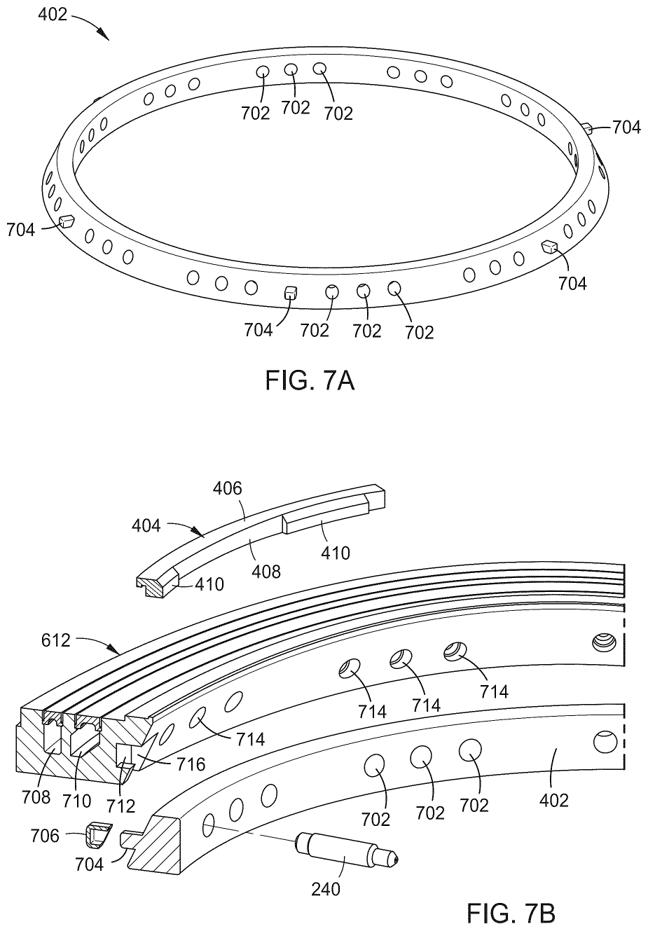

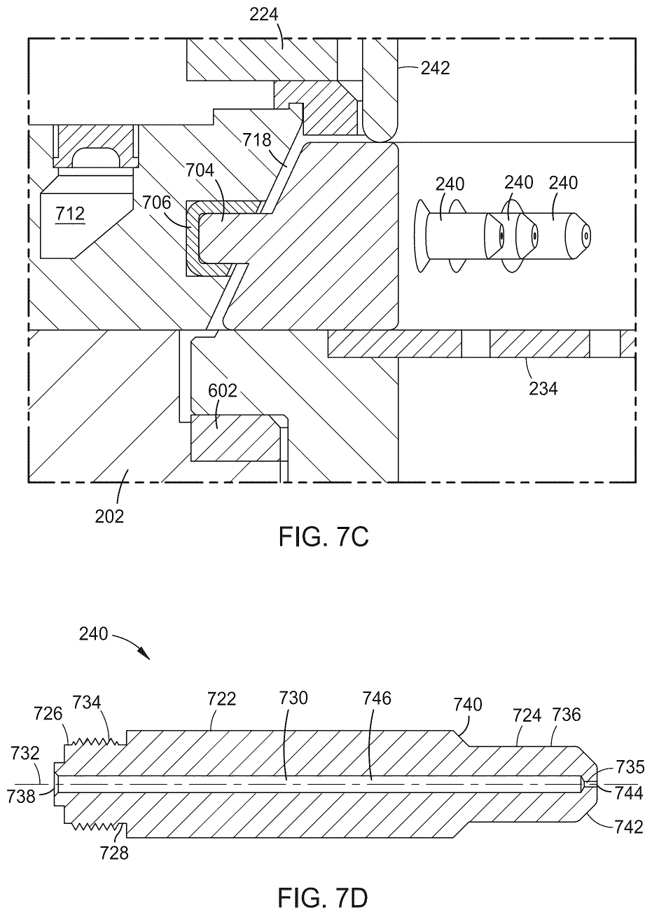

In some embodiments, the processing chamber 200 includes a ring heating assembly 295 that is configured to control the temperature of the gas ring 612 (FIGS. 6 and 7B) and gas ring liner 402 to a temperature greater than room temperature, such as a temperature greater than 100° C., or greater than 150° C., or greater than 175° C., or even greater than 200° C. The ring heating assembly 295 includes a heating element 296 and a heating source 297. In one configuration, the heating element 296 includes a resistive heating element that is disposed within a body portion of either the gas ring liner 402 or gas ring 612. The embedded resistive heating element can be heated by delivering an electrical current provided from an AC or DC electrical power source within the heating source 297. In another configuration, the heating element 296 is a fluid channel formed within the gas ring 612 that is heated or cooled by the delivery of a fluid flow provided from a fluid heating device or heat exchanging device within the heating source 297. In some embodiments, the controller 144 is configured to cause the heating assembly 295 to control the temperature of the gas ring liner 402 and gas ring 612 to a temperature of at least 170° C. to prevent condensation of one or more process gases in the embedded lines or nozzles during processing, such as an epitaxial layer deposition gas that includes aluminum chloride (AlCl₃) or germanium chloride (GeCl₃).

FIG. 4A illustrates a schematic cross-sectional view of the processing chamber 200 according to an embodiment. Similar components in FIGS. 2A, 2B, and 4A are indicated with identical reference numerals. Comparing with FIGS. 2A and 2B, FIG. 4A further shows that a plurality of side nozzles 240a, 240b, and 240c are coupled to a gas ring liner 402. According to an embodiment, each process gas may have a dedicated side gas nozzle. For example, the carrier gas may flow through the gas nozzle 240a, the deposition gas may flow through the gas nozzle 240b, and the cleaning gas may flow through the gas nozzle 240c. According to another embodiment, one side gas nozzle may be shared by a plurality of process gases. The side gas nozzles 240a, b and c are evenly distributed around the gas ring liner 420. In one example, a total of 36 side gas nozzles 240 are provided. In some embodiments, one or more of the side gas nozzles 240 are made of a dielectric material, such as quartz (SiO₂), boron nitride (BN), alumina (Al₂O₃), aluminum nitride (AlN), silicon nitride (SiNₓ), or other suitable material. In one embodiment, the side gas nozzles 240 are made of metal oxide (e.g., Al₂O₃) or metal nitride material (e.g., AlN, SiNₓ, etc.) that is coated with corrosion-resistant material, such as a yttrium oxide material (e.g., Y₂O₃). In one embodiment, the side gas nozzles 240 are made of a composite material, such as an alumina (e.g., Al₂O₃) and boron nitride (BN) material, or an alumina (e.g., Al₂O₃) and yttrium oxide material (e.g., Y₂O₃) material, or a boron nitride (BN) material and a yttrium oxide material (e.g., Y₂O₃).

The gas ring liner 402 is disposed between the lid liner 242 and the wall liner 248. The wall liner 248 is configured to support both the gas ring liner 402 and, optionally, the showerhead 234. As noted above, FIG. 2B illustrates a configuration that does not include the showerhead 234, and thus the processing region 246 and plenum region 238 form a larger processing volume (i.e., plasma processing region 253) over the substrate 210 in which both regions are in direct communication with each other and the substrate 210. The lid liner 242 rests at a top surface 412 of the gas ring liner 402. A clearance gap is formed between the lid liner 242 and the dome lid 224. A plurality of separators 404 are disposed in the clearance gap to maintain the clearance. The lid liner 242, the gas ring liner 402, and the wall liner 248 may be made of materials having low thermal conductance and/or having resistance to the etch chemistry occurred inside the processing chamber. For example, the lid liner 242 is made of quartz or ceramic. In some embodiments, one or more of the lid liner 242, the gas ring liner 402, charge screen 312 (FIG. 3), and the wall liner 248 are made of a metal, such as stainless steel, aluminum, titanium, or other suitable metal, that is coated with a corrosion-resistant coating layer. In one example, the gas ring liner 402 includes a stainless steel (e.g., 304 or 316 SST) material that is coated with an aluminum oxide (Al₂O₃) and/or yttrium oxide (Y₂O₃) layer formed by use of a chemical vapor deposition (CVD) or atomic layer deposition (ALD) process. The liners also protect other chamber parts from cleaning or deposition process chemistries, which, for example, can contain chlorine (Cl) containing gases. The separators 404 are used to prevent the lid and gas ring liners from contacting other parts. The separators 404 may be made of materials that are stable in a wide temperature working range and inert to process gases. For example, the separators 404 may be made of polytetrafluoroethylene (PTFE), perfluoroalkoxy alkane (PFA), or other suitable materials. According to an embodiment, the separators 404 may be disposed at a top surface 416 (FIG. 4B) of the gas ring liner 402 and set predetermined clearance between the lid liner 242 and the dome lid 224 and between the gas ring liner 402 and the dome lid 224. The separators 404 may be in the form of a continuous ring or be formed by a plurality of segments distributed along the top surface 416 of the gas ring liner 402.

As shown in FIG. 4B, the separators 404 includes at least two separated segments 404a and 404b. According to an embodiment, each segment 404a and 404b covers a predetermined arc angle, such as about 15 to 60 degrees, and in one example is about 45 degrees or 30 degrees. Each segment 404a and 440b has a dome contact side 406 and a liner contact side 408. The dome contact side 406 maintains a continuous contact with the dome lid 224, while the liner contact side 408 includes a few discrete protrusions 410 configured to contact the lid liner 242. Other surface areas of the liner contact side 408 do not in contact with the lid liner 242.

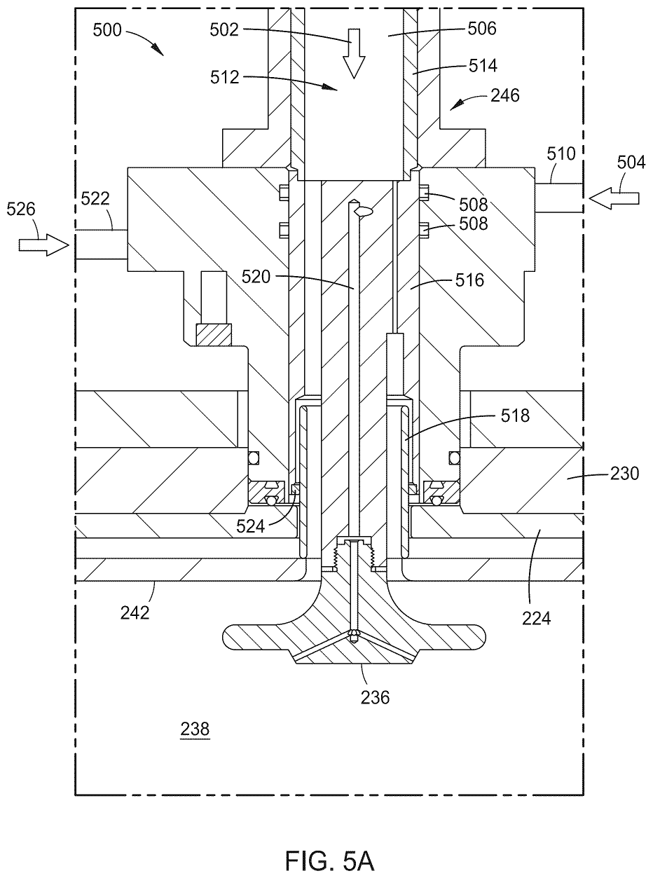

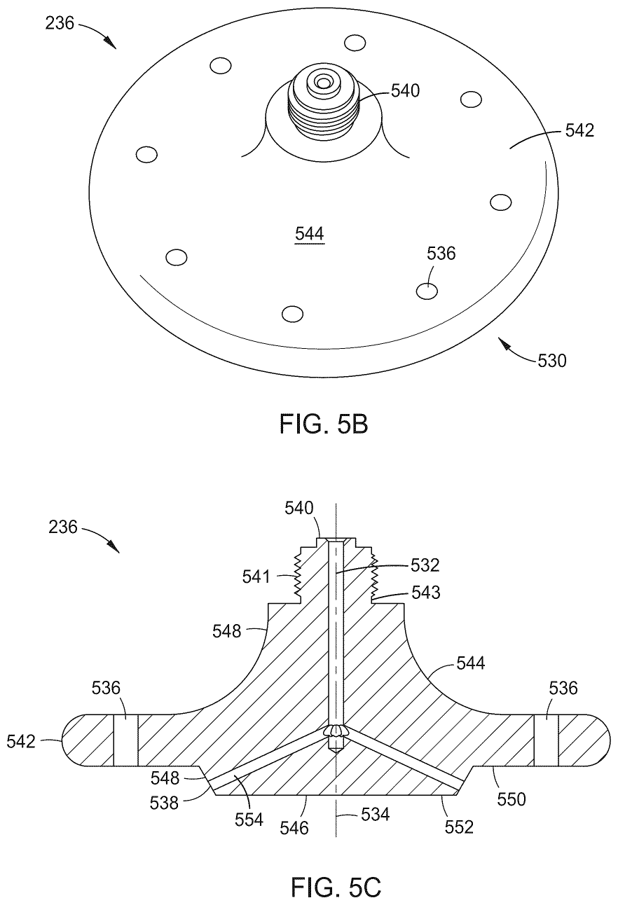

FIG. 4A also shows a gas baffle 236 that extends through the dome lid 224 and the lid liner 242 and into the gas plenum region 238 of the processing chamber 200. The configuration of Callout 4-A, including the gas baffle, will be explained in detail in FIG. 5A. The construction configuration of Callout 4-B will be explained in detail in FIG. 6.

FIG. 5A illustrates the configuration of Callout 4-A in FIG. 4A, according to an embodiment. The gas feed section 500 includes a carrier gas conduit 512 for a process gas 502 and a gas pipe 510 for the deposition/cleaning gas (e.g., process gas 504). A plasma chamber 506 is disposed at an upper part of the carrier gas conduit 512, where a remote plasma source 252 energizes a cleaning gas (e.g., HCl, Cl₂, CCl₄, etc.), process gas (e.g., H₂), and/or carrier gas provided from the gas sources 232 into a plasma state to generate radicals that are applied to the processing region 246 and plenum region 238, for example, during a cleaning process, or epitaxial deposition process. The energized gases (e.g., carrier gas 502) flows downwardly in the conduit 512 to enter the gas plenum region 238. The process gas 504 flows from the gas pipe 510 into a deposition/cleaning gas conduit 520. The gas pipe 510 may further include a plasma chamber coupled with a remote plasma source to energize the deposition/cleaning gas. The remote plasma source may be configured to generate a plasma in the gas pipe 510 by use of an RF source (e.g., 13.56 MHz source) or a microwave source (e.g., 1 GHz-3 GHz source). Two radial seals 508 are disposed above and below the gas pipe 510 along the gas conduit 512. According to an embodiment, the gas pipe 510 is disposed in a direction substantially perpendicular to the gas conduit 520. The carrier gas conduit 512 and the deposition/cleaning gas conduit 520 are substantially coaxial. The process gas 504 flows downward in the conduit 520 into the gas baffle 236 which spreads the deposition/cleaning gas in the gas plenum region 238. Another plasma source 230, such as an inductively coupled plasma source, may be disposed at a top surface of the dome lid 224 to energize the gas mixture in the gas plenum region 238.

The gas conduit 512 is protected by a plurality of liners. A plasma chamber liner 514 is disposed within the plasma chamber 506. The carrier gas conduit 512 is protected by two liners: a first liner 518 and a second liner 516. The first liner 518 is disposed at the bottom part of the carrier gas conduit 512 and couples the lid liner 242 with the carrier gas conduit 512. The second liner 516 engages with the first liner 516 via an aligner 524 and couples the first liner 518 with the plasma chamber liner 514. This split liner design eases the alignment and installation process when the gas feed section 500 is assembled. According to an embodiment, the plasma chamber liner 514, the first liner 518, and the second liner 518 may be made of quartz or other suitable materials. The aligner 524 may be made of PTFE or other suitable materials. In some embodiments, the plasma chamber liner 514, the first liner 518, and the second liner 516 may be made of quartz, boron nitride (BN), and/or coated with a corrosion-resistant material (e.g., yttria), or formed from other suitable materials as discussed further herein.

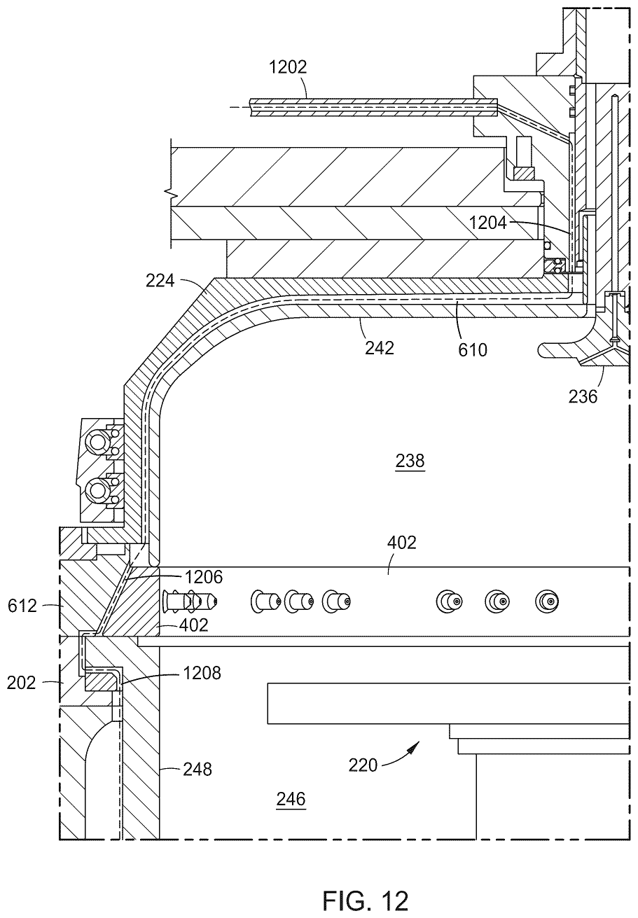

The gas feed section 500 further includes a purge gas pipe 522 for a purge gas. As gaps exist between the internal liners and the dome lid and side walls of the processing chamber 200, process gases could have leaked into those gaps and may generate deposits. The purge gas pipe 522 is configured to flow a purge gas 526 into the gaps to prevent the process gases and/or plasma from entering the gap. The purge gas pipe 522 is coupled with the gaps at a location right below the gas pipe 510 and provides the purge gas into those gaps. To allow the purge gas 526 to flow into those gaps, the aligner 524, the separator 404, and the gas ring liner 402 include openings at pre-determined locations for the purge gas 526 to flow through. The flow path of the purge gas 526 will be shown and explained in detail later with reference to FIG. 12.

FIGS. 5B and 5C illustrate schematic perspective and cross-sectional views of the top baffle 236, respectively, according to an embodiment of the present application. The top baffle 236 includes a coupling part 540, an extension part 544, a disk body 542, and a bottom part 546. The top baffle 236 includes a plurality of first channels 532 and 554 for delivering the process gas 504 and a plurality of second channels 536 for delivering the process gas 502.

The coupling part 540 couples the top baffle 236 with the gas liner 516 via a thread 541 or any other suitable coupling mechanism. A groove 543 is formed between the coupling part 540 and the extension part 544 and configured to receive a gas seal. The process gas 504 flows inside the top baffle 236 via the channel 532 that is disposed vertically along an axis 534 of the top baffle 236. The process gas 502 flows along an external surface 548 of the top baffle 236.

The extension part 544 allows the top baffle 236 to have an adequate clearance from the lid liner 242. The extension part 544 also allows the top baffle 236 to reach a predetermined depth within the gas plenum region 238. The extension part 544 is configured to extend radially outward from the coupling part 540 to direct the process gas 502 away from the axis 534 of the top baffle 236. According to an embodiment, an external surface 548 of the extension part 544 represents a quarter circle that extends from the coupling part 540 to the disk body 542.

The disk body 542 has a substantially circular shape 530. The disk body 542 includes a plurality of gas channels 536 that allow the process gas 502 to flow through. The plurality of gas channels 536 are arranged in parallel to the axis 534. The extension part 544 and the channels 536 together distribute the process gas 502 into the gas plenum region 238.

The bottom part 546 has a circular shape with a smaller diameter than the diameter of the disk body 542. The bottom part 546 extends from a bottom surface 550 of the disk body 542. A beveled surface 548 is formed between the bottom surface 550 of the disk body 542 and a bottom surface 552 of the bottom part 546. The beveled surface 548 includes a plurality of dispensing outlets 538 of a plurality of channels 554, which direct the process gas 504 radially outward from the channel 532. In this way, the process gas 504 can be distributed more evenly into the gas plenum region 238. According to an embodiment, the channel 554 and the vertical channel 532 form an angle of about 60 degrees.

FIG. 6 illustrates a construction configuration of Callout 4-B in FIG. 4A according to an embodiment. The lid liner 242, the gas ring liner 402, and the wall liner 248 may rest on top of each other as they can be made of similar materials, such as quartz. For example, a lower end 608 of the lid liner 242 rests on a top surface 614 of the gas ring liner 402, whose bottom surface 616 rests on an upper end 604 of the wall liner 248. The wall liner 248 is configured to couple with both the gas ring liner 402 and, optionally, the showerhead 234. According to an embodiment, the upper end 604 of the wall liner 248 is substantially “L” shaped. The cantilever extension 618 of the upper end 604 couples with a separator 602, which separates the wall liner 248 from the side wall 202. The separator 602 may be made of PTFE or similar materials. According to an embodiment, the wall liner 248 has an open lower end 620 to allow process gas to flow through. According to an embodiment, the upper end 604 includes an optional cutout 606 configured to couple with the showerhead 234. The optional cutout 606 has a thickness similar with the showerhead 234 such that after the showerhead 234 is disposed within the cutout 606, the top surface of the showerhead 234 is flushed with the top surface of the upper end 604. The gas ring liner 402 rests on both the showerhead 234 and the wall liner 248. In this way, the showerhead 234 is snuggly sandwiched by the gas ring liner 402 and the wall liner 248. In a configuration that does not include the showerhead 234, the gas ring liner 402 rests on the wall liner 248.

As shown in FIG. 6, the separator 404 separates both the lid liner 242 and the gas ring liner 402 from other outside components, such as the lid 224 and a gas ring 612. According to an embodiment, the separator 404 maintains a clearance gap 610 between the dome lid 224 and the lid liner 242.

FIGS. 7A-7C illustrate configurations between a gas ring liner 402 and a gas ring 612 according to an embodiment. A gas ring 612 is disposed between the dome lid 224 and the side walls 202 to provide process gases into the side nozzles 240. The gas ring 612 includes a plurality of concentric gas channels 708, 710, and 712 configured to flow process gases to respective side nozzles 240. The gas ring 612 further includes a plurality of apertures 714 that couple with the side nozzles 240. The gas ring 612 may further couple with the separator 404 having a plurality of protrusions 410 as shown in FIG. 4B. The gas ring liner 402 is disposed inward of the gas ring 612 to protect and insulate the gas ring 612 from the process gases and the heat. The gas ring liner 402 includes a plurality of apertures 702, a plurality of tabs 704, and a plurality of separators 706. The plurality of apertures 702 align with the plurality of apertures 714 of the gas ring 612 such that the side nozzles 240 extend through both apertures. The plurality of tabs 704 engage with corresponding depressions 716 disposed in the gas ring 612 such that the gas ring liner 402 is properly aligned with the gas ring 612 and radial movement of the gas ring liner 402 may be mitigated. As the gas ring liner 402 and the gas ring 612 may be made of different materials, each tab 704 may have a separator 706 for maintaining a clearance gap 718 with the gas ring 612 to accommodate thermal expansion. The separator 706 may be made of PTFE or other suitable materials.

In some embodiments, the plurality of concentric gas channels 708, 710 within the gas ring 612 are coupled together to allow a cleaning gas (e.g., Cl₂, HCl) provided in and through the outer concentric gas channel 708 by a gas source (e.g., gas source 232) to be supplied into and through the inner concentric gas channel 710, and then out the side nozzles 240 coupled to the inner concentric gas channel 710 to remove any residual deposited material or other contaminants from the inner concentric gas channel 710 and side nozzles 240. In this configuration, the materials and/or contaminants left over from prior epitaxial deposition processes can be removed during a subsequent cleaning process since the surfaces that come into contact with the deposition process gases (e.g., silane (SiH₄) and dopant gases (e.g., PH₃)) provide into the inner concentric gas channel 710 are within a cleaning gas flow path that extends from the outer concentric gas channel 708 through the inner concentric gas channel 710 and through the nozzles 240. As noted above, the gas ring liner 402 can include a base material (e.g., metal) that has all exposed surfaces coated with a corrosion-resistant material layer (e.g., yttria, alumina, aluminum nitride, etc.) that is formed by use of a chemical vapor deposition (CVD) or atomic layer deposition (ALD) process.

FIG. 7D illustrates a schematic cross-sectional view of a side nozzle 240, according to an embodiment of the present application. The side nozzle 240 has a cylindrical shape with a central axis 732. The side nozzle 240 includes a coupling part 726, an extension body 722, and a nozzle part 724, each having a cylindrical shape but with different diameters. The coupling part 726 is configured to couple with the gas ring 612 and has an orifice 738 to allow a process gas to flow into a channel 730 disposed within the side nozzle 240. The coupling part 726 may couple with the gas ring 612 via any suitable coupling mechanisms, such as a plurality of threads 734. A protrusion 725 is disposed around the orifice 738 and extends from a bottom surface of the coupling part 726. The protrusion 725 is configured to couple with the aperture 714 via a separator made of PTFE. A groove 728 is formed between the coupling part 726 and the extension body 722 and is configured to accommodate a gas seal. The extension part 722 has a larger diameter than the coupling part 726. The extension part 722 has a length that is about the same as the thickness of the gas ring liner 402 to allow the nozzle part 724 to be positioned inside the gas plenum region 238.

The nozzle part 724 has a smaller diameter than the extension body 722 to reduce obstruction of gas flow inside the gas plenum region 238. The nozzle part 724 includes a first beveled part 740, a support body 736, a second beveled part 742, and a dispenser outlet 744. The first beveled part 740 connects the extension body 722 with the support body 736. The second beveled part 742 connects the support body 736 with the dispenser outlet 744.

The channel 730 extends along the axis 732 from the orifice 738 to the dispenser outlet 744. According to an embodiment, the channel 730 includes a first segment 746 and a second segment 735. The first segment 746 traverses the coupling part 726, the extension body 722, and a portion of the nozzle part 724. The second segment 735 is entirely disposed within the nozzle part 724 and couples directly with the dispenser outlet 744. According to an embodiment, a diameter of the second segment 735 is smaller than a diameter of the first segment 746.

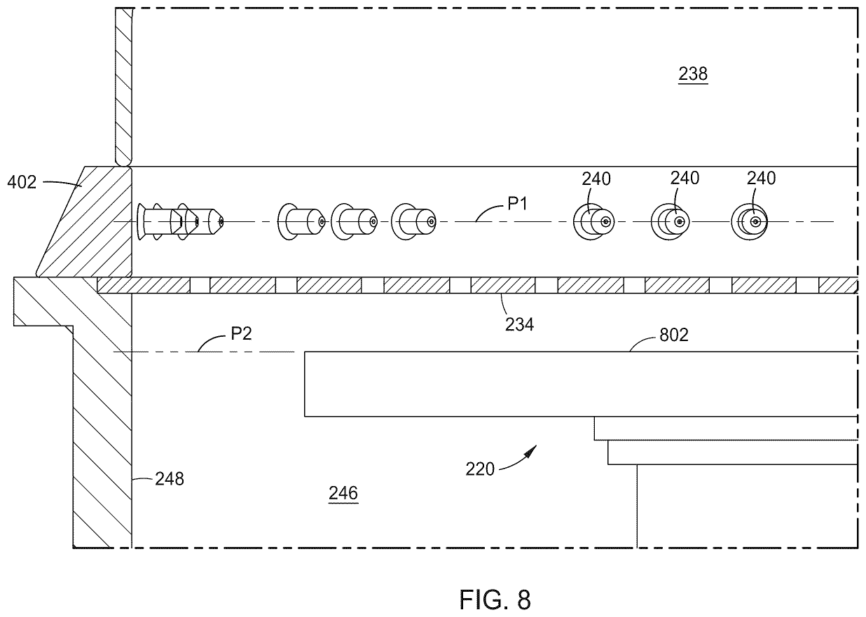

FIG. 8 illustrates a schematic configuration of the processing chamber including the optional showerhead 234 and the susceptor 220, according to an embodiment. The showerhead 234 rests on the wall liner 248 and is disposed between the plurality of side nozzles 240 and a top surface 802 of the susceptor 220. For example, the distance between the showerhead 234 and a plane P1 passing the centers of the plurality of the side nozzles 240 may be approximately equal to the distance between the showerhead 234 and a plane P2 passing the top surface 802 of the susceptor 220.

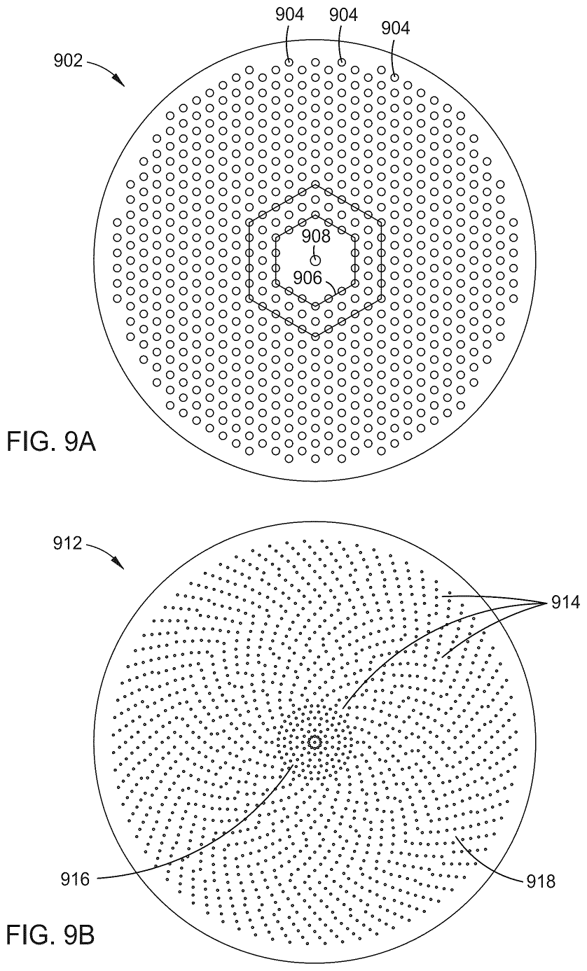

FIG. 9A illustrates a schematic top view of a showerhead according to an embodiment. The showerhead 902 of FIG. 9A may include a plurality of through apertures 904 that allow process gases to flow through. According to an embodiment, the plurality of through apertures 904 are arranged in a plurality of equal sided hexagons 906 that share a common center 908 of the showerhead 902. According to an embodiment, the apertures 904 are disposed equidistantly along the perimeter of each hexagon. According to an embodiment, the sizes of the apertures 904 are between 0.1 to 0.4 inch.

FIG. 9B illustrates a schematic top view of a showerhead according to an embodiment. The showerhead 912 includes a plurality of apertures 914, whose sizes are relatively small, such as between 0.01 to 0.08 inch, compared to the apertures 904 of the showerhead 902. The arrangement of the apertures 914 may include a plurality of patterns. For example, around a central zone 916 of the showerhead 912, a plurality of apertures 914 are disposed in concentric circles, while at the peripheral areas 918 of the showerhead 912, a plurality of apertures are disposed in a zigzag pattern.

According to an embodiment, the showerhead 234 is made of a dielectric material, such as quartz, sapphire, alumina, boron nitride (Pyrolytic), or other suitable material. A dielectric showerhead 234 allows the gas to be energized at a high power level to flow through and reach the surface of a substrate 210. According to another embodiment, the showerhead 234 is made of a conductive material, such as aluminum coated with alumina or silicon or a passivated layer, or other suitable material. A conductive showerhead 234 will allow more radicals to reach the surface of a substrate.

FIG. 10A illustrates a schematic cross-sectional view of the susceptor 220 according to an embodiment. The susceptor 220 includes a top cover 1002, a heater body 1012, a bottom cover 1004, a column support cover 1006, and a column support 1022. In an example, the heater body 1012 and the column support 1022 are made of aluminum nitride, boron nitride, or aluminum oxide. According to an embodiment, the top cover 1002 and the bottom cover 1004 are made of materials resistant to process gases, such as chlorine gas or chlorine-containing gas mixtures. In one example, the top cover 1002 and the bottom cover 1004 are made of boron nitride (paralytic-) (PBN). The column support cover 1006 may be made of similar materials as the top cover 1002 and bottom cover 1004. The top cover 1002, the bottom cover 1004, and the column support cover 1006 are configured to encapsulate substantially all surfaces of the heater body 1012 and the column support 1022 to protect them from corrosion by process gases. According to an embodiment, the top cover 1002 contacts with a substrate 210 and has a high thermal conductivity. The bottom cover 1004 is configured to reduce thermal loss and has a low thermal conductivity. According to an embodiment, the top cover 1002 is configured to have a higher thermal conductivity than the bottom cover 1004.

According to an embodiment, the susceptor 220 further includes a plurality of heat transfer channels disposed within the susceptor 220 configured to assist heat transfer to the surface area of the heater body 1012. Details of the heat transfer channels will be described with reference to FIGS. 10B and 10C.

The heater body 1012 is covered by the top cover 1004, the bottom cover 1004, and the column support cover 1006. According to an embodiment, the heater body 012 is substantially T-shaped with a horizontal cap 1030 coupled with a column support 1022. The top cover 1002 and the bottom cover 1004 overlay each other where they meet to avoid exposing the heater body 1012 to the process gases. The top cover 1002, the bottom cover 1004, and the heater body 1012 include a plurality of lift pin holes 1010, 1026, and 1028, respectively. The lift pin holes 1010, 1026, and 1028 are aligned with each other to allow lift pins to pass through. According to an embodiment, the top cover 1002 further includes a plurality of alignment pins 1032 disposed at a central location of the top cover 1002. The heater body 1012 includes a plurality of alignment depressions 1034 to receive the alignment pins 1032. The alignment pins 1032 and depression 1034 are configured to align lift pin holes 1010 in the top cover and the lift pin holes 1028 in the heater body 1012. According to an embodiment, alignment pins are also disposed in the bottom cover 1004.

The column support 1022 is protected by a column support cover 1006, which is also made of a corrosion-resistant material, such as a chlorine-resistant material. The column support 1022 and the column support cover 1006 are coupled with each other coaxially. The column support cover 1006 overlaps with the bottom cover 1004 to prevent process gas from contacting the heater body 1012. A plurality of electrical connections 1014 are disposed within the column support 1022.

FIG. 10B illustrates a schematic top view of the heater body 1012 according to an embodiment. The plurality of channels 1044 are disposed on a top surface 1042 of the heater body 1012. In one embodiment, the plurality of channels 1044 are configured to transfer inert gases, such as argon gas or any other suitable gases, to the peripheral areas of the heater body 1012 to maintain a constant rate of heat transfer across the entire heater surface. The plurality of channels includes inner channels 1046, branch channels 1048, and peripheral channels 1050. The inner channels 1046 couple with the alignment depression 1034 and are configured to distribute the gases from the alignment depressions 1034 to the branch channels 1048. The branch channels 1048 are configured to provide the gases from the inner channels 1046 to the peripheral channels 1050 that cover a substantial amount of peripheral areas. In one example, the inner channels 1046 form a circle around an axis 1052 of the heater body 1012. The branch channels 1048 are straight channels configured to lower the resistance when gases are delivered from inner channels to the peripheral channels. The peripheral channels 1050 also form a circle that is coaxial with the inner channels 1046.

FIG. 10C illustrates a schematic cross-sectional view of the heater body 1012. The column support 1022 includes a plurality of gas channels 1058 disposed in parallel with the axis 1052. The plurality of gas channels 1058 are coupled with the plurality of channels 1044 (also shown in FIG. 10B) via the alignment depressions 1034. The column support 1022 further includes a main channel 1054 coupled with both a gas inlet 1018 (shown in FIG. 10A) and a branch channel 1056. Purge gases flow from the gas inlet 1018 to the main channel 1054 and then to the branch channel 1056, which distributes the gases to the plurality of gas channels 1058. In one embodiment, the number of gas channels 1058 is the same as the number of the alignment depressions 1034.

During operation, the column support cover 1006 and the heater body 1012 may be lifted together by a lifter 244 (shown in FIG. 3). Thus, a sleeve 1016 attached to the bottom 204 (shown in FIG. 3) is included to provide a conduit to guide the movement of the column support cover 1006 and the heater body 1012. According to an embodiment, the column support cover 1006 and the sleeve 1016 engage with each other to form a gas-tight seal. In one example, the column support cover 1006 includes a bottom flange 1024 that engages with an end of the sleeve 1016 to form a gas tight seal when the column support cover 1006 is lifted up. The bottom flange 1024 may include a groove. According to another embodiment, the column support cover 1006 also includes a bottom purge flange 1020 having a plurality of gas inlets 1018. The plurality of gas inlets 1018 are coupled with purge gas inlets 304 (shown in FIG. 3) configured to flow purge gas to the space or volume inside the column support cover 1006. The purge gas creates a positive pressure inside the column support cover 1006, which can prevent process gas from entering the inside of the column support cover 1006, depositing materials inside the column support 1022, and corroding the heater body 1012.

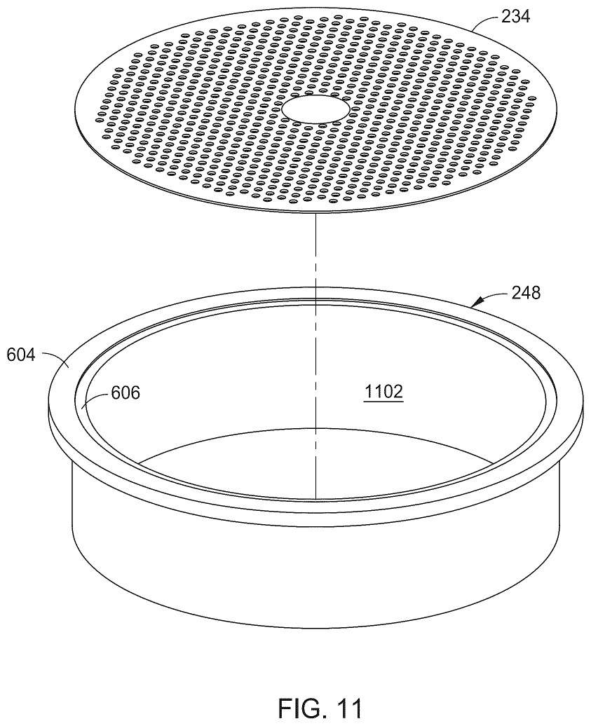

FIG. 11 illustrates a schematic perspective view of a wall liner 248 according to an embodiment. The wall liner 248 has a cylindrical shape with an open end 1102 that allows the process gases to flow through. A vacuum pump 214 (FIG. 2A) is disposed below the wall liner 248 to remove the process gases. The wall liner 248 has an upper end 604 that has an “L” shape. The upper end 604 has a cantilever extension configured to couple with the side wall 202 (FIG. 2A) of the processing chamber 200 via a separator. The upper end 604 further includes a cutout 606 configured to couple with the showerhead 234.

FIG. 12 illustrates a schematic flow path of a purge gas according to an embodiment of the present application. When the liners are disposed between other outside parts of the processing chamber 200 and an internal region, gaps are created between the liners and other outside parts. For example, a gap 1204 is created between the conduit liners 514, 516, 518 and the conduits 512. Another gap 610 is created between the lid liner 242 and the dome lid 224. Yet another gap 1206 is created between the gas ring 612 and the gas ring liner 402. And yet another gap 1208 is created between the wall liner 248 and the side walls 202. As these gaps are not completely sealed from the process gases, these gaps are filled with a purge gas to prevent the process gases from entering during substrate processing. The purge gas prevents any deposition of materials in these gaps and possible contamination during the processing of the next substrate.

According to an embodiment, gaps between the liners and outside parts are configured to be fluidly coupled with each other such that a purge gas can flow from one gap to another. As shown in FIG. 12, a purge gas pipe 1202 is coupled with the gap 1204 at a location right below the process gas pipe. The purge gas pipe 1202 is configured to flow a purge gas, such as an inert gas, with pressure into the gap 1204. With the pressure from the purge gas pipe 1202 and the vacuum from the vacuum pump 214 at the bottom, the purge gas flows from the gap 1204 to the gap 610, the gap 1206, and the gap 1208, and then exits the processing chamber 200 via the vacuum pump 214. The dash line shown in FIG. 12 indicates the flow path of the purge gas in the processing chamber 200. According to an embodiment, to allow the purge gas flow through the gaps, the separators are configured to have intermittent openings that couple adjacent gaps.

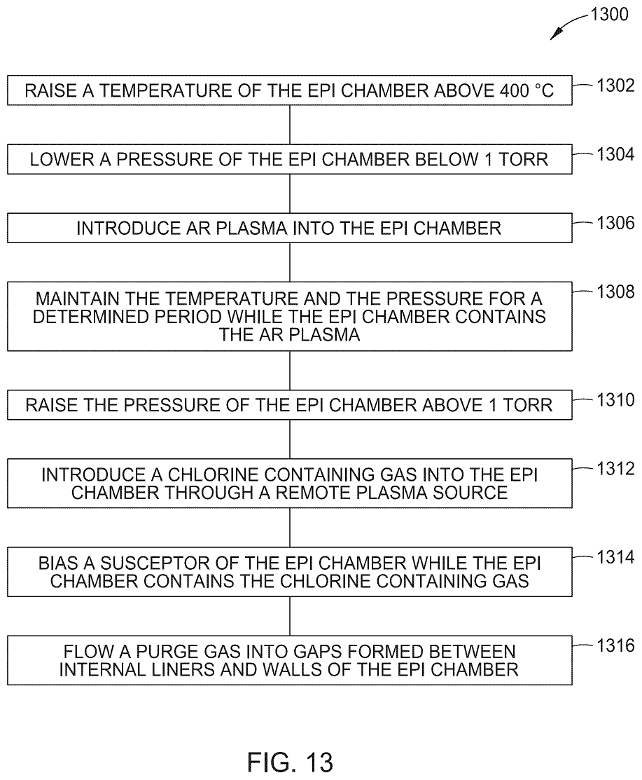

FIG. 13 illustrates a block diagram of a cleaning method 1300 of the EPI chamber according to an embodiment. The in-situ chamber cleaning process cleans chamber walls and the susceptor. The in-situ chamber cleaning process may use a chlorine containing gas. A plasma may also be generated during the cleaning process. The temperature of the susceptor may be increased before the cleaning process and decreased after the cleaning process. The cleaning method 1300 starts with operation 1302 which raises a temperature of the EPI chamber above about 400° C. At operation 1304, the pressure of the EPI chamber is lowered below about 100 m Torr, such as between 5 and 20 mTorr. At operation 1306, an argon plasma is introduced into the EPI chamber. The plasma source disposed around the chamber walls may also be activated to further energize the argon plasma. At operation 1308, the temperature and the pressure are maintained for a determined period while the EPI chamber contains the argon plasma. The argon plasma is continuously introduced. At operation 1310, the pressure of the EPI chamber is maintained or adjusted to a proper range suitable to strike a chlorine plasma. At operation 1312, a chlorine containing gas (e.g., Cl₂, HCl) is introduced into the EPI chamber while the argon plasma is maintained. The power to generate the argon plasma will be increased due to the introduction of the chlorine containing gas. The chlorine containing gas is introduced for a predetermined period to assist the cleaning of surfaces previously exposed to the argon plasma. At operation 1314, a purge gas may be flowed into gaps formed between internal liners and walls of the EPI chamber. The operation 1314 may be implemented together with any operations of the cleaning method 1300. According to an embodiment, the operation 1314 is implemented before introducing the chlorine containing gas into the chamber to protect certain surfaces that may not be compatible with the chlorine containing gas.

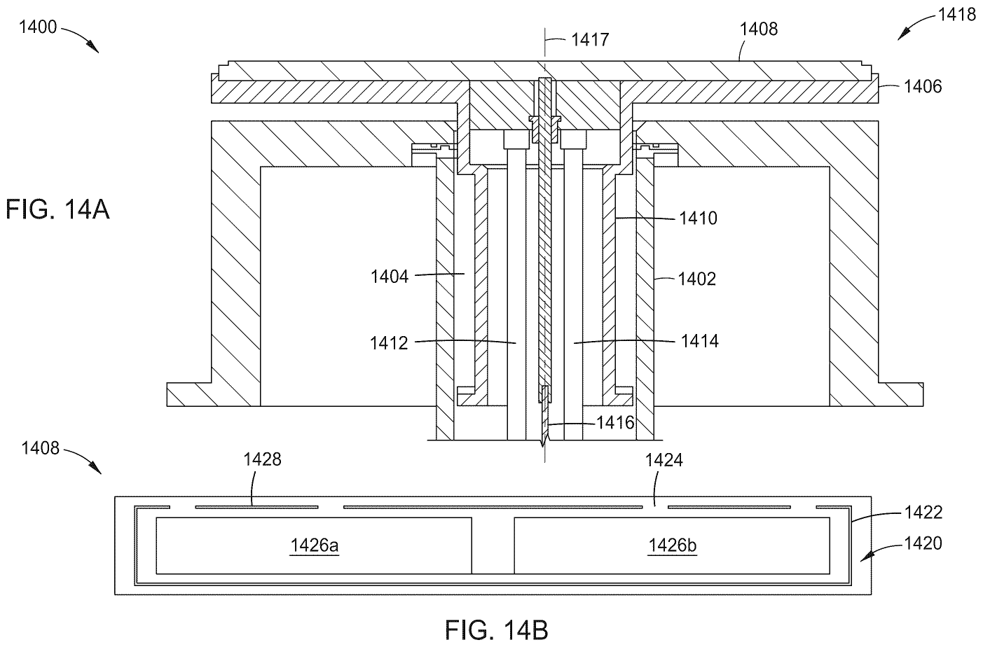

FIG. 14A illustrates a schematic cross-sectional view of a susceptor 1400, according to an embodiment. The susceptor 1400 includes a heater puck 1408, a support body 1406, and a shaft 1410. The heater puck 1408 is disposed on the support body 1406 and includes a plurality of resistive heating elements (such as 1428 shown in FIG. 14B) configured to heat a substrate disposed on the heater puck 1408. The heater puck 1408 includes a rim 1418 disposed around the perimeter. The rim 1418 forms a pocket that contains the heater puck 1408. The support body 1406 is coupled with the shaft 1410. The shaft 1410 can be raised up and lowered down by an actuator (such as the lifter 244 in FIG. 2A). A sleeve 1402 surrounds the shaft 1410 with a certain clearance space 1404 to allow the shaft 1410 move up and down. The clearance space 1404 also functions as a purged clearance space 1404, which is filled with a pressured purge gas, such as an argon gas, during a substrate processing. The pressured purged gas prevents process gases from entering the internal space of the susceptor 1400.

The susceptor 1400 further includes a plurality of electric conduits 1412 and 1414 configured to allow electric wires to pass through. The susceptor 1400 may also include channel 1416 disposed along a central axis 1417 of the susceptor 1400. The electric conduit 1414 allows a temperature probe to measure the temperature of the heater puck 1408.

FIG. 14B illustrates a schematic cross-sectional view of the heater puck 1408, according to an embodiment. The heater puck 1408 includes a plurality of graphite cores 1426a and 1426b that are enclosed by a first protective layer 1424. The first protective layer 1424 may be made of boron nitride (paralytic-) (PBN). The plurality of resistive heating elements 1422 are disposed on the first protective layer 1424 and then covered by a second protective layer 1420. The second protective layer 1420 may be made of a material similar with that of the first protective layer 1424. Each graphite core 1426a or 1426b is enclosed by the first protective layer 1424. The first protective layer 1424 and the second protective layer 1420 may be formed by two coatings of PBN or by sintering two plates made of PBN.

In some embodiments of the processing chamber 200 and/or processing system 100, 1500, the temperature of the heating-related portions (e.g., heating element 209) of the susceptor 220 and the temperature of the electrode 220d are monitored and controlled by use of the heating unit 222 and commands from the controller 144. In some embodiments, based on the temperature of the electrode 220d and heating-related portions of the susceptor 220, the controller 144 may adjust the impedances (e.g., capacitances) of one or more of the matches (e.g., match circuit 279b, match circuit 231c, match circuit 231d, etc.) to better control the plasma impedance during processing due to the susceptor's impedance changing as a function of temperature.

Benefits of the present disclosure include enhanced processing (such as deposition, etching, and/or cleaning), low temperature processing (such as low temperature epitaxial deposition), and low pressure processing. The plasma assisted deposition process described allows for a deposition process to be performed at a temperature under 500 degrees Celsius (such as 400 degrees Celsius or less). This lower temperature allows for the formation of improved semiconductor substrates. The benefits further include improved gas flow control, decreased maintenance, decreased cost, and increased component lifetime. The present disclosure beneficially provides a chlorine plasma compatible chamber which enables in-situ choline chamber clean at a lower temperature.

### Configuration Examples

Implementations of the plasma enhanced epitaxial chamber disclosed herein may include one or more of the following. An ICP source with RF generator operating from 100 kHz to 13 MHz. An ICP source with coils organized flat on a dielectric window, which is composed of Al₂O₃ or AlN. An ICP source with coils organized on a dielectric window with varying geometries including but not limited to concentric coils with multiple turns extending vertically, or planar coils with an additional concentric vertically extending coil with multiple turns. An ICP source where the power ratio between the inner and outer coils can be modified for tunability. An ICP source where the power is operating <2 kW and has fine tunability at low powers, 500 W, 600 W, 700 W to 2 kW. An ICP source where the generator has pulsing capability to decrease the average delivered power. An ICP source with substrate to source spacing from 5.5″ to 11.5″ from substrate to source. A CCP plasma source with RF generator operating at frequencies from 13 MHz to 400 MHz. A CCP plasma source with the substrate grounded and the lid RF hot, or the lid grounded and substrate RF hot. A capacitively coupled plasma (CCP) source where the generator has pulsing capability to decrease average power. A microwave source with generator operating from 500 MHz to 5 GHz. A chamber with an ICP or microwave source, which has a bias electrode located beneath the substrate. A chamber with a remote plasma source to generate radical species utilized for epitaxial growth or in situ etch. A chamber with a remote plasma source which is lined with quartz and coated with Al₂O₃, SiO₂, or Y₂O₃ for Cl compatibility. A bias electrode which is driven by 400 kHz-27 MHz generator. A bias electrode which has RF pulsing capability and/or pulsed voltage (PVT) capability to decrease average power. A bias electrode which is operating with <300 W. A plasma epi chamber with substrate edge to chamber radial distance from 2.5″ to 7.5″. The plasma epitaxial chamber is lined with chlorine compatible material such as —SiO₂ (quartz), Al₂O₃, Y₂O₃, pBN, YAG, or AlON. The plasma epitaxial chamber is constructed from metal components coated with chlorine compatible materials such as —SiO₂ (quartz), Al₂O₃, Y₂O₃, pBN, YAG, or AlON. The coating can be applied via thermal spray, plasma spray, PVD, CVD, or ALD. The chamber includes gas injection components manufactured from Cl compatible materials such as SiO₂ (quartz), Al₂O₃, Y₂O₃, pBN, YAG, or AlON. The chamber includes gas injection components cooled to <300C to prevent deposition within the component's gas cavity. The chamber includes gas delivery lines constructed from Cl corrosion resistant materials such as Hastelloy or a metal coated with a Cl resistant coating such as —SiO₂ (quartz), Al₂O₃, Y₂O₃, pBN, YAG, or AlON. The chamber includes gas delivery lines heated to >100C to desorb H₂O from the gas line surface. Desorption of water is to avoid corrosion of metallic gas lines by diatomic chlorine (Cl₂). The chamber includes particulate filters installed before the chamber gas inlet with Cl compatible membranes such as PTFE and Hastelloy bodies. The chamber includes precursor gas purifiers to reduce gaseous H₂O, O₂, and/or N₂ levels to <1 ppb concentration levels. The chamber includes a heat source which is Cl compatible to increase the substrate temperature to >250C. The heat source is a resistive heater. The resistive heater is encapsulated or coated within a Cl compatible material such as SiO₂ (quartz), Al₂O₃, Y₂O₃, pBN, YAG, or AlON. The heat source is a radiant heater encapsulated within a Cl compatible material such as SiO₂ (quartz), Al₂O₃, Y₂O₃, pBN, YAG, or AlON. The chamber includes a turbomolecular pump to achieve HV or UHV pressure levels. The turbomolecular pump has an outlet >=50 mm. The chamber includes a foreline diameter that is >4″ and up to 8″. The chamber includes a roughing pump which has a hydrogen pumping speed >1000 m³/hr at 200 mTorr. The chamber includes a foreline heated to above 100C. The platform that the plasma epitaxial chamber is mounted on, for example, Applied's Endura® system platform or Centura® system platform, is coated with Cl resistant materials such as nickel, SiO₂, Al₂O₃, Y₂O₃, etc. The platform has high vacuum or ultra-high vacuum capabilities. The platform is a dual cluster platform where both the front and back platform have a turbo pump, and the plasma epitaxial chamber is located on the back cluster where a lower pressure can be achieved. The chamber body is heated to temperatures >100C. The platform includes the epitaxial growth chamber integrated with pre-clean chambers, for example, Applied's Siconi and AEF oxide preclean chambers, or a C (Ajax) preclean chamber. The platform has purge gas capability to increase mainframe pressure to be higher than that of the chamber pressure before substrate transfer.

Disclosed herein is an EPI chamber for a low-temperature EPI growth and components of the same. The EPI chamber includes a susceptor that conductively heats a substrate using a resistive heater. A radiative heat source may not be needed in the EPI chamber of the present application, essentially reducing the frequency to clean the dome of the EPI chamber. The substrate temperature during processing is controlled to be below 800° C., 600° C., 500° C., or even lower. The Epi growth rates at these low temperatures are compensated by increasing gas/plasma temperature and activating the surface (compensating lower surface temperature) of the substrate to increase mobility of adatoms landed on the substrate surface. Thus, one or more plasma sources are included in the EPI chamber for energizing the process gas. The plurality of plasma sources may be disposed around pipes of gas feeds, above and/or below the showerhead around the dome lid and/or side walls of the EPI chamber.

To reduce energy loss to the environment and protect the other parts of the EPI chamber from erosion, the EPI chamber includes a plurality of internal liners that thermally isolate the dome and side walls of the EPI chamber from internal heat. As the liners are made of materials of low thermal conductance, such as quartz, and are different from the dome and walls of the EPI chamber, the internal liners are separated from adjacent parts by separators to avoid thermal stress caused by mismatch of coefficient of thermal expansion (CTE). A purging process is implemented to prevent unnecessary deposition of materials or byproducts in the gaps between the internal liners and outside parts, and to prevent possible contamination during the processing of the next substrate.

To provide axisymmetric gas flow into the processing region, a gas feed with a plurality of feeding locations is included in the dome of the EPI chamber. The gas feed further includes a plurality of side nozzles disposed right above the showerhead around the side walls of the dome lid. A gas ring couples the plurality of the side nozzles and is protected by a gas ring liner. Optionally, the process gases may be provided to a gas plenum first and then flow through a showerhead into a processing region above the susceptor.

### Plasma Processing Chamber Examples

Embodiments of the disclosure include a plasma processing chamber that comprises a substrate support, a chamber lid, an inductively coupled plasma source, a gas ring, and a lower portion of the plasma processing chamber comprising an enclosure. The substrate support comprising a substrate supporting surface disposed in a plasma processing region of the plasma processing chamber. The chamber lid is positioned over the substrate supporting surface and the plasma processing region. The inductively coupled plasma source is positioned over the chamber lid and operable to energize a process gas disposed within the plasma processing region. The inductively coupled plasma source comprises a first coil positioned over the chamber lid, wherein the first coil comprises a first end and a second end, a radio frequency (RF) power source, wherein an output node of the RF power source is coupled to the first end of the first coil, and a second coil, wherein the second coil comprises a first end and a second end, the first end of the second coil is coupled to the second end of the first coil, and the second end of the second coil is coupled to ground. The gas ring is disposed under the chamber lid. The gas ring comprises a plurality of nozzles that are configured to deliver a gas through an outlet of each of the nozzles to a portion of the plasma processing region disposed over the substrate supporting surface. The lower portion of the plasma processing chamber comprising an enclosure having an axis of symmetry, wherein a pumping port formed in the enclosure and the substrate support are concentrically aligned about the axis of symmetry of the enclosure. An axis of symmetry of a pumping port formed in the enclosure and an axis of symmetry of the substrate support can be substantially colinear with the axis of symmetry of the enclosure. Embodiments of the plasma processing chamber may further comprise: a vacuum pump coupled to the pumping port, wherein the vacuum pump is concentrically aligned with the pumping port. In some embodiments, the plurality of nozzles are each configured to deliver the gas in a radial direction.

Embodiments of the plasma processing chamber disclosed herein may further include a substrate bias source comprising a first power source coupled to an electrode of the substrate support. The electrode is disposed within a body of the substrate support, wherein the substrate supporting surface of the substrate support is disposed over the electrode.

Embodiments of the plasma processing chamber disclosed herein may further include: a first matching circuit electrically coupled between the output node of the RF power source and the first end of the first coil, wherein the first matching circuit comprises a first series capacitor and a first shunt capacitor; and a second matching circuit electrically coupled between the second end of the second coil and ground, wherein the second matching circuit comprises one or more capacitors that each include a first end that is coupled to the second end of the second coil and a second end that is coupled to ground.

Embodiments of the plasma processing chamber disclosed herein may further include a matching circuit that comprises one or more capacitors that each include a first end that is coupled to the second end of the second coil and a second end that is coupled to ground.

Embodiments of the plasma processing chamber disclosed herein may further comprise a first plasma source disposed around walls above the gas ring and a second plasma source disposed around walls below the gas ring.

Embodiments of the plasma processing chamber disclosed herein may further comprise a remote plasma source coupled to an opening in the chamber lid, wherein the remote plasma source comprises a conduit liner disposed between a plasma generation region of the remote plasma source and an outlet of the remote plasma source that is coupled to the opening, and wherein the remote plasma source is configured to provide gas atom radicals to the plasma processing region, and the conduit liner comprises quartz.

Embodiments of the plasma processing chamber disclosed herein may further comprise a heating element coupled to a body portion of the gas ring, wherein the heating element is configured to heat a gas flowing through a channel formed in the body portion of the gas ring, and the outlet of each of the nozzles is in fluid communication with the channel.

Embodiments of the plasma processing chamber disclosed herein may further comprise a gas ring liner positioned adjacent to the gas ring, wherein the gas ring liner comprises: a dielectric material selected from a group consisting of quartz, alumina, and yttria; and a plurality of openings formed therethrough, wherein a nozzle of the plurality of nozzles is disposed within an opening of the plurality of openings.

Embodiments of the plasma processing chamber disclosed herein may further comprise a heating element coupled to a body portion of the gas ring, wherein the heating element is configured to heat a gas flowing through a channel formed in the body portion of the gas ring, and the outlet of each of the nozzles is in fluid communication with the channel. The plasma processing chamber may further include a gas ring liner positioned adjacent to the gas ring, wherein the gas ring liner comprises: a dielectric material selected from a group consisting of quartz, alumina, and yttria; and a plurality of openings formed therethrough, wherein a nozzle of the plurality of nozzles is disposed within an opening of the plurality of openings.

Embodiments of the disclosure may further include a plasma processing chamber that comprises a substrate support, a chamber lid, a first inductively coupled plasma source, a second inductively coupled plasma source, a substrate bias source, a gas ring, and a lower portion of the plasma processing chamber comprising an enclosure. The substrate support comprises a substrate supporting surface disposed in a plasma processing region of the plasma processing chamber. The chamber lid is positioned over the substrate supporting surface and the plasma processing region. The first inductively coupled plasma source is positioned over the chamber lid and operable to energize a process gas disposed within the plasma processing region. The first inductively coupled plasma source comprises a first coil positioned over the chamber lid, wherein the first coil comprises a first end and a second end, and the second end of the first coil is coupled to ground, and a first radio frequency (RF) power source, wherein an output node of the first RF power source is coupled to the first end of the first coil. The second inductively coupled plasma source that is operable to energize the process gas disposed within the plasma processing region. The second inductively coupled plasma source comprises a second coil positioned over the chamber lid, wherein the second coil comprises a first end and a second end, and the second end of the second coil is coupled to ground, and a second radio frequency (RF) power source, wherein an output node of the second RF power source is coupled to the first end of the second coil. The gas ring is disposed under the chamber lid, wherein the gas ring comprises a plurality of nozzles that are configured to deliver a gas through an outlet of each of the nozzles to a portion of the plasma processing region disposed over the substrate supporting surface. The lower portion of the plasma processing chamber comprises an enclosure having an axis of symmetry, wherein a pumping port formed in the enclosure and the substrate support are concentrically aligned about the axis of symmetry of the enclosure.

Embodiments of the disclosure may further include a plasma processing chamber that comprises a substrate support, a chamber lid, a first inductively coupled plasma source, a substrate bias source, a gas ring, a heating element coupled to a body portion of the gas ring, and a lower portion of the plasma processing chamber comprising an enclosure. The substrate support comprises a substrate supporting surface disposed in a plasma processing region of the plasma processing chamber. The chamber lid is positioned over the substrate supporting surface and the plasma processing region. The first inductively coupled plasma source is positioned over the chamber lid and operable to energize a process gas disposed within the plasma processing region, wherein the first inductively coupled plasma source comprises: a first coil positioned over the chamber lid, wherein the first coil comprises a first end and a second end, and the second end of the first coil is coupled to ground; and a first radio frequency (RF) power source, wherein an output node of the first RF power source is coupled to the first end of the first coil. The gas ring is disposed under the chamber lid, wherein the gas ring comprises a plurality of nozzles that are configured to deliver a gas through an outlet of each of the nozzles to a portion of the plasma processing region disposed over the substrate supporting surface. The heating element is configured to heat a gas flowing through a channel formed in the body portion of the gas ring, and the outlet of each of the nozzles is in fluid communication with the channel. The lower portion of the plasma processing chamber comprises an enclosure having an axis of symmetry, wherein a pumping port formed in the enclosure and the substrate support are concentrically aligned about the axis of symmetry of the enclosure.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A plasma processing chamber for forming an epitaxial layer, the plasma processing chamber comprising:
a substrate support comprising:
an electrode disposed within a body of the substrate support; and
a substrate supporting surface disposed over the electrode and in a plasma processing region of the plasma processing chamber;
a chamber lid positioned over the substrate supporting surface and the plasma processing region;
an inductively coupled plasma source positioned over the chamber lid and operable to energize a process gas disposed within the plasma processing region, wherein the inductively coupled plasma source comprises:
a first coil positioned over the chamber lid, wherein the first coil comprises a first end and a second end;
a radio frequency (RF) power source, wherein an output node of the RF power source is coupled to the first end of the first coil; and
a second coil, wherein
the second coil comprises a first end and a second end,
the first end of the second coil is coupled to the second end of the first coil, and
the second end of the second coil is coupled to ground;
a substrate bias source, wherein the substrate bias source comprises a first power source that is coupled to the electrode of the substrate support;
a gas ring disposed under the chamber lid, wherein the gas ring comprises a plurality of nozzles that are configured to deliver a gas through an outlet of each of the nozzles to a portion of the plasma processing region disposed over the substrate supporting surface; and
a lower portion of the plasma processing chamber comprising an enclosure having an axis of symmetry, wherein a pumping port formed in the enclosure and the substrate support are concentrically aligned about the axis of symmetry of the enclosure.

2. The plasma processing chamber of claim 1, further comprising:
a first matching circuit electrically coupled between the output node of the RF power source and the first end of the first coil, wherein the first matching circuit comprises a first series capacitor and a first shunt capacitor; and
a second matching circuit electrically coupled between the second end of the second coil and ground, wherein the second matching circuit comprises one or more capacitors that each include a first end that is coupled to the second end of the second coil and a second end that is coupled to ground.

3. The plasma processing chamber of claim 1, further comprising:
a matching circuit that comprises one or more capacitors that each include a first end that is coupled to the second end of the second coil and a second end that is coupled to ground.

4. The plasma processing chamber of claim 1, further comprising a first plasma source disposed around walls above the gas ring and a second plasma source disposed around walls below the gas ring.

5. The plasma processing chamber of claim 1, wherein an axis of symmetry of a pumping port formed in the enclosure and an axis of symmetry of the substrate support are substantially colinear with the axis of symmetry of the enclosure.

6. The plasma processing chamber of claim 5, further comprising:
a vacuum pump coupled to the pumping port, wherein the vacuum pump is concentrically aligned with the pumping port.

7. The plasma processing chamber of claim 1, wherein the plurality of nozzles are each configured to deliver the gas in a radial direction.

8. The plasma processing chamber of claim 1, further comprising:
a remote plasma source coupled to an opening in the chamber lid, wherein the remote plasma source comprises a conduit liner disposed between a plasma generation region of the remote plasma source and an outlet of the remote plasma source that is coupled to the opening, and wherein
the remote plasma source is configured to provide gas atom radicals to the plasma processing region, and
the conduit liner comprises quartz.

9. The plasma processing chamber of claim 1, further comprising:
a heating element coupled to a body portion of the gas ring, wherein the heating element is configured to heat a gas flowing through a channel formed in the body portion of the gas ring, and the outlet of each of the nozzles is in fluid communication with the channel.

10. The plasma processing chamber of claim 9, further comprising:
a gas ring liner positioned adjacent to the gas ring, wherein the gas ring liner comprises:
a dielectric material selected from a group consisting of quartz, alumina, and yttria; and
a plurality of openings formed therethrough, wherein a nozzle of the plurality of nozzles is disposed within an opening of the plurality of openings.

11. A plasma processing chamber for forming an epitaxial layer, the plasma processing chamber comprising:
a substrate support comprising:
an electrode disposed within a body of the substrate support; and
a substrate supporting surface disposed over the electrode and in a plasma processing region of the plasma processing chamber;
a chamber lid positioned over the substrate supporting surface and the plasma processing region;
a first inductively coupled plasma source positioned over the chamber lid and operable to energize a process gas disposed within the plasma processing region, wherein the first inductively coupled plasma source comprises:
a first coil positioned over the chamber lid, wherein the first coil comprises a first end and a second end, and the second end of the first coil is coupled to ground; and
a first radio frequency (RF) power source, wherein an output node of the first RF power source is coupled to the first end of the first coil;
a second inductively coupled plasma source that is operable to energize the process gas disposed within the plasma processing region, wherein the second inductively coupled plasma source comprises:
a second coil positioned over the chamber lid, wherein the second coil comprises a first end and a second end, and the second end of the second coil is coupled to ground; and
a second radio frequency (RF) power source, wherein an output node of the second RF power source is coupled to the first end of the second coil;
a substrate bias source, wherein the substrate bias source comprises a first power source that is coupled to the electrode of the substrate support;
a gas ring disposed under the chamber lid, wherein the gas ring comprises a plurality of nozzles that are configured to deliver a gas through an outlet of each of the nozzles to a portion of the plasma processing region disposed over the substrate supporting surface; and
a lower portion of the plasma processing chamber comprising an enclosure having an axis of symmetry, wherein a pumping port formed in the enclosure and the substrate support are concentrically aligned about the axis of symmetry of the enclosure.

12. The plasma processing chamber of claim 11, further comprising:
a first matching circuit electrically coupled between the output node of the first RF power source and the first end of the first coil, wherein the first matching circuit comprises a first series capacitor and a first shunt capacitor; and
a second matching circuit electrically coupled between the second end of the first coil and ground, wherein the second matching circuit comprises one or more capacitors that each include a first end that is coupled to the second end of the first coil and a second end that is coupled to ground.

13. The plasma processing chamber of claim 11, further comprising:
a matching circuit that comprises one or more capacitors that each include a first end that is coupled to the second end of the first coil and a second end that is coupled to ground.

14. The plasma processing chamber of claim 11, wherein an axis of symmetry of a pumping port formed in the enclosure and an axis of symmetry of the substrate support are substantially colinear with the axis of symmetry of the enclosure.

15. The plasma processing chamber of claim 14, further comprising:
a vacuum pump coupled to the pumping port, wherein the vacuum pump is concentrically aligned with the pumping port.

16. The plasma processing chamber of claim 11, wherein the plurality of nozzles are each configured to deliver the gas in a radial direction.

17. The plasma processing chamber of claim 11, further comprising:
a remote plasma source coupled to an opening in the chamber lid, wherein the remote plasma source comprises a conduit liner disposed between a plasma generation region of the remote plasma source and an outlet of the remote plasma source that is coupled to the opening, and wherein
the remote plasma source is configured to provide gas atom radicals to the plasma processing region, and
the conduit liner comprises quartz.

18. The plasma processing chamber of claim 11, further comprising:
a heating element coupled to a body portion of the gas ring, wherein the heating element is configured to heat a gas flowing through a channel formed in the body portion of the gas ring, and the outlet of each of the nozzles is in fluid communication with the channel.

19. The plasma processing chamber of claim 18, further comprising:
a gas ring liner positioned adjacent to the gas ring, wherein the gas ring liner comprises:
a dielectric material selected from a group consisting of quartz, alumina, and yttria; and
a plurality of openings formed therethrough, wherein a nozzle of the plurality of nozzles is disposed within an opening of the plurality of openings.

20. A plasma processing chamber for forming an epitaxial layer, comprising:
a substrate support comprising:
an electrode disposed within a body of the substrate support; and
a substrate supporting surface disposed over the electrode and in a plasma processing region of the plasma processing chamber;
a chamber lid positioned over the substrate supporting surface and the plasma processing region;
a first inductively coupled plasma source positioned over the chamber lid and operable to energize a process gas disposed within the plasma processing region, wherein the first inductively coupled plasma source comprises:
a first coil positioned over the chamber lid, wherein the first coil comprises a first end and a second end, and the second end of the first coil is coupled to ground; and
a first radio frequency (RF) power source, wherein an output node of the first RF power source is coupled to the first end of the first coil;
a substrate bias source, wherein the substrate bias source comprises a first power source that is coupled to the electrode of the substrate support;
a gas ring disposed under the chamber lid, wherein the gas ring comprises a plurality of nozzles that are configured to deliver a gas through an outlet of each of the nozzles to a portion of the plasma processing region disposed over the substrate supporting surface;
a heating element coupled to a body portion of the gas ring, wherein the heating element is configured to heat a gas flowing through a channel formed in the body portion of the gas ring, and the outlet of each of the nozzles is in fluid communication with the channel; and
a lower portion of the plasma processing chamber comprising an enclosure having an axis of symmetry, wherein a pumping port formed in the enclosure and the substrate support are concentrically aligned about the axis of symmetry of the enclosure.

21. The plasma processing chamber of claim 20, further comprising:
a matching circuit that comprises one or more capacitors that each include a first end that is coupled to the second end of the first coil and a second end that is coupled to ground.

22. The plasma processing chamber of claim 20, further comprising:
a gas ring liner positioned adjacent to the gas ring, wherein the gas ring liner comprises:
a dielectric material selected from a group consisting of quartz, alumina, and yttria; and
a plurality of openings formed therethrough, wherein a nozzle of the plurality of nozzles is disposed within an opening of the plurality of openings.
